(19) United States
(12) Patent Application Publication
(10) Pub. No.: US 2025/0189571 A1
(43) Pub. Date: Jun. 12, 2025

(54) ELECTROMAGNETIC WAVE DETECTION DEVICE

(71) Applicants: Mitsubishi Electric Corporation, Tokyo (JP); TMEIC CORPORATION, Tokyo (JP)

(72) Inventors: Yusuke YAMAKAJI, Tokyo (JP); Takahiro MIZUGUCHI, Tokyo (JP); Moe KITANO, Tokyo (JP)

(73) Assignees: Mitsubishi Electric Corporation, Tokyo (JP); TMEIC CORPORATION, Tokyo (JP)

(21) Appl. No.: 19/059,699

(22) Filed: Feb. 21, 2025

Related U.S. Application Data
(63) Continuation of application No. PCT/JP2022/032304, filed on Aug. 29, 2022.

(51) Int. Cl. G01R 29/08

(52) U.S. Cl. CPC G01R 29/0878

(57) ABSTRACT

An electromagnetic wave detection device is one to detect an electromagnetic wave from an electromagnetic wave generation source in a second space partitioned by a partition plate to attenuate propagation of the electromagnetic wave from a first space in which the electromagnetic wave generation source is disposed, the electromagnetic wave detection device including an electromagnetic wave observation unit including: a metal wire having a penetrating portion to penetrate a through hole formed in the partition plate while being separated from a peripheral wall of the through hole; a protruding portion to protrude from the penetrating portion to the first space and receive the electromagnetic wave from the electromagnetic wave generation source; and an extending portion extending from the penetrating portion to the second space, in which one end portion located on the second space side is connected to a ground point located on the second space side.

### CROSS REFERENCE TO RELATED APPLICATIONS

This application is a Continuation of PCT International Application No. PCT/JP2022/032304 filed on Aug. 29, 2022, all of which is hereby expressly incorporated by reference into the present application.

### TECHNICAL FIELD

The present disclosure relates to an electromagnetic wave detection device that detects an electromagnetic wave from an electromagnetic wave generation source to be measured.

### BACKGROUND ART

An electromagnetic wave detection device that detects an electromagnetic wave in order to know an abnormality of an electronic device or the like is known, and as one such electromagnetic wave detection device, an insulation monitoring device of a metal-closed distribution board that detects a partial discharge electromagnetic wave generated by an insulation abnormality is proposed by Patent Literature 1.

Patent Literature 1 discloses an insulation monitoring device of a metal-closed distribution board in which a discharge detection unit, including an antenna for detecting an electromagnetic wave and an amplifier for amplifying a detection signal of the antenna, is disposed in a housing of the metal-closed distribution board, and an insulation determination unit for monitoring presence or absence of a signal component due to an electromagnetic wave generated from an output signal of the amplifier due to partial discharge caused at the time of insulation abnormality is provided.

### CITATION LIST

### Patent Literature

Patent Literature 1: JP 2005-265684 A

### SUMMARY OF INVENTION

### Technical Problem

Since the insulation monitoring device disclosed in Patent Literature 1 is intended for a metal-closed distribution board, a discharge detection unit that detects an electromagnetic wave is disposed of in the housing of the metal-closed distribution board.

On the other hand, there is a demand for an electromagnetic wave detection device that detects an abnormality by disposing of an electromagnetic wave detection device in a space in which an electromagnetic wave generation source to be measured is disposed of and a different space divided by a partition plate that attenuates an electromagnetic wave such as metal and detecting an electromagnetic wave from the electromagnetic wave generation source.

The present disclosure has been made in view of the above points, and an object of the present disclosure is, in a first space in which an electromagnetic wave generation source is disposed and a second space partitioned by a partition plate that attenuates propagation of an electromagnetic wave and different from the first space, to obtain an electromagnetic wave detection device capable of detecting, in the second space, an electromagnetic wave from the electromagnetic wave generation source disposed of in the first space.

### Solution to Problem

An electromagnetic wave detection device according to the present disclosure is an electromagnetic wave detection device comprising an electromagnetic wave observation unit and a detecting unit, the detecting unit disposed of in a second space partitioned from a first space in which the electromagnetic wave generation source is disposed of by a partition plate to attenuate propagation of an electromagnetic wave and in which there is not the electromagnetic wave generation source, the electromagnetic wave observation unit including a metal wire having a penetrating portion to penetrate a through hole formed in the partition plate through the first space and the second space while being separated from a peripheral wall of the through hole, a protruding portion to protrude from the penetrating portion to the first space apart from a surface of the partition plate without contact and receive the electromagnetic wave from the electromagnetic wave generation source, and an extending portion to extend from the penetrating portion to the second space apart from a rear surface of the partition plate without contact and a coil connected between one end of the extending portion of the metal wire and the ground point, wherein the detecting unit detects a voltage between both terminals of the coil.

### Advantageous Effects of Invention

According to the present disclosure, detection of an electromagnetic wave from an electromagnetic wave generation source disposed in a first space can be performed with good sensitivity in a second space by using an electromagnetic wave observation unit having a simple structure including a metal wire having a penetrating portion, a protruding portion protruding to the first space, and an extending portion 13 extending to the second space, and a coil connected between one end of the extending unit of the metal wire and the ground point, by detecting a voltage between both terminals of coils by the detecting unit, while the current based on the electromagnetic wave received by the protruding portion due to parasitic components occurred between the protruding portion and the partition plate is suppressed to flow directly to the partition plate through parasitic components from the protruding portion, enabling to receive a voltage between both terminals of the coil by the detecting unit and is avoided to lower S/N ratio.

### BRIEF DESCRIPTION OF DRAWINGS

FIG. 1 is a configuration diagram illustrating an electromagnetic wave detection device according to a first embodiment.

FIG. 2 is a configuration diagram illustrating an electromagnetic wave detection device according to a second embodiment.

FIG. 3 is a configuration diagram illustrating an electromagnetic wave detection device according to a third embodiment in which a conductor plate is partially broken.

FIG. 4 is a configuration diagram illustrating an electromagnetic wave detection device according to a fourth embodiment.

FIG. 5 is a diagram illustrating a relationship between the frequency of an electromagnetic wave emitted from an electromagnetic wave generation source and a received signal strength measured by a measurement unit in an electromagnetic wave detection device according to the fourth embodiment.

FIG. 6 is a configuration diagram illustrating an electromagnetic wave detection device according to a fifth embodiment.

FIG. 7 is a configuration diagram illustrating an electromagnetic wave detection device according to a sixth embodiment.

FIG. 8 is a configuration diagram illustrating an electromagnetic wave detection device according to a seventh embodiment.

FIG. 9 is a configuration diagram illustrating an electromagnetic wave detection device according to an eighth embodiment.

FIG. 10 is a configuration diagram illustrating an electromagnetic wave detection device according to a ninth embodiment.

FIG. 11 is a diagram illustrating a relationship between the frequency of an electromagnetic wave emitted from an electromagnetic wave generation source and a received signal strength measured by a measurement unit in the electromagnetic wave detection device according to the ninth embodiment.

FIG. 12 is a configuration diagram illustrating an electromagnetic wave detection device according to a tenth embodiment.

FIG. 13 is a diagram illustrating a receiving unit in a protruding portion of a metal wire in the electromagnetic wave detection device according to the tenth embodiment.

FIG. 14 is a diagram illustrating a receiving unit in a protruding portion of a metal wire in an electromagnetic wave detection device according to an eleventh embodiment.

FIG. 15 is a diagram illustrating a receiving unit in a protruding portion of a metal wire in an electromagnetic wave detection device according to a twelfth embodiment.

FIG. 16 is a diagram illustrating a receiving unit in a protruding portion of a metal wire in an electromagnetic wave detection device according to a thirteenth embodiment.

FIG. 17 is a diagram illustrating a receiving unit in a protruding portion of a metal wire in an electromagnetic wave detection device according to a fourteenth embodiment.

FIG. 18 is a diagram illustrating a receiving unit in a protruding portion of a metal wire in an electromagnetic wave detection device according to a fifteenth embodiment.

FIG. 19 is a configuration diagram illustrating an electromagnetic wave detection device according to a sixteenth embodiment.

FIG. 20 is a configuration diagram illustrating an electromagnetic wave detection device according to a seventeenth embodiment.

FIG. 21 is a configuration diagram illustrating an electromagnetic wave detection device according to a nineteenth embodiment.

### DESCRIPTION OF EMBODIMENTS

### First Embodiment

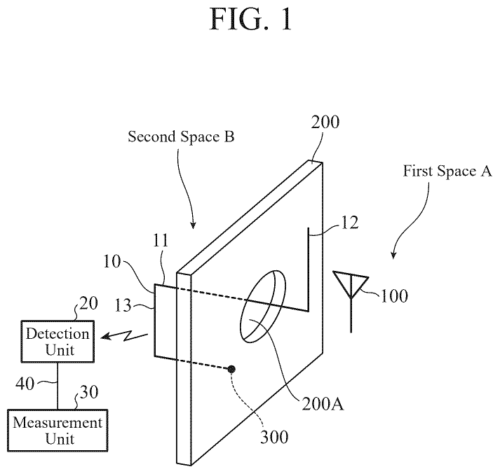

An electromagnetic wave detection device according to a first embodiment will be described with reference to FIG. 1.

The electromagnetic wave detection device according to the first embodiment is disposed in a second space B partitioned by a partition plate 200 that attenuates the propagation of the electromagnetic wave from a first space A in which an electromagnetic wave generation source 100 is disposed and detects an electromagnetic wave from the electromagnetic wave generation source 100.

The electromagnetic wave detection device according to the first embodiment includes an electromagnetic wave observation unit 10, a detection unit 20, and a measurement unit 30.

First, before describing the electromagnetic wave detection device, the electromagnetic wave generation source 100, the first space A, the second space B, and the partition plate 200 will be described.

The content described below is not limited to the first embodiment and is common to other embodiments.

### [Electromagnetic Wave Generation Source 100]

The electromagnetic wave generation source 100 targets, for example, the following (a) to (f).

### <<Abnormality Detection Based on Partial Discharge Due to Aging Deterioration of Insulator>

When the insulator in the electromagnetic wave generation source 100 is normal, partial discharge does not occur, and partial discharge occurs in the insulator between the conductors in the following cases. By monitoring this partial discharge, the electromagnetic wave detection device according to the present disclosure performs abnormality detection.

Since the electromagnetic wave due to the partial discharge is a signal having a large voltage rise, that is, a large temporal change of the voltage, the electromagnetic wave includes many high-frequency signals.

### <<Cause of Occurrence of Partial Discharge>>

Aging deterioration of the insulator, or adhesion of dust or a nitride oxide or the like generated by oxidation of nitrogen in the air by weak discharge to the insulator.
Contact failure due to the weak fitting of the connector attached to the end of the cable.
Oxidation of the conductor inside the cable or deterioration of the insulator due to condensation or being placed a long time in a high-humidity environment.
Voids (voids) generated between the metal wire and the insulator coating due to the application of repetitive vibrations.
Voids generated in the insulator coating due to the application of repetitive vibrations.

### <<Target>>

(a) A component in an electronic device housed in a housing of an electronic device. Examples thereof include an electronic component, a semiconductor device, a transforming coil, and a motor.

Note that the housing of the electronic device does not need to have an electromagnetic shield structure. The housing may have any structure that attenuates electromagnetic waves. For example, the housing may have a punching metal having a plurality of holes, a mesh structure including a wire, only a resin, a metal-plated resin, a resin-coated metal, or a combination of a resin and a metal.

In addition to electromagnetic waves used in televisions, radios, mobile phones, and the like, electromagnetic waves generated in nature such as lightning and static electricity, electromagnetic waves generated from the inside of the electronic device, and electromagnetic waves generated from other electronic devices may be present inside the housing of the electronic device.

(b) A component that generates an electromagnetic wave due to partial discharge in an electrical device. Examples thereof include an insulator of a high-voltage distribution board, a circuit breaker, a bushing of a transformer of an oil type, a mold type, or the like, a conductor of a bus duct, a main circuit terminal of a rectifier, and a main circuit terminal of a generator (for a windmill or the like).

(c) Transmission line.

(d) A component covered with an insulator in which partial discharge occurs due to aging deterioration. Examples thereof include an electrode of an electronic device, a main circuit terminal motor of an electric motor, a motor for an automobile, and a compressor of an air conditioner, each having a voltage of 100 V or more.

Although the discharge generation voltage greatly changes depending on conditions such as the environment, the discharge generation voltage is a voltage equal to or lower than Paschen's law or modified Paschen's law. This is because Paschen's law, or modified Paschen's law, indicates a voltage at which spark discharge occurs between electrodes, and it is known that partial discharge occurs at a lower voltage than spark discharge.

### <<Detection of Abnormality Due to Electromagnetic Wave Generated in Cable>>

(e) For example, the cable is a cable to which a high voltage is applied, a cable through which a large current flow, or a cable to which vibration is likely to be applied structurally.

By monitoring the current flowing through the cable, the electromagnetic wave detection device, according to the present disclosure, detects an abnormality in the cable itself or the inside of the electric device to which the cable is connected.

In this example, since an abnormality inside the electrical device is generated as an electromagnetic wave after being propagated to the cable, the cable is regarded as the electromagnetic wave generation source 100.

### <<Abnormality Detection Inside Semiconductor Device>

(f) A semiconductor device disposed inside an electromagnetic shield.

By monitoring the surge voltage generated inside the semiconductor device, the abnormality can be detected by the electromagnetic wave detection device according to the present disclosure.

The electromagnetic wave generation source 100 includes an electronic device, an electrical device, a component in the electric device, a component in the electronic device, an electromagnetic wave generation source arranged in a factory, a power plant, or a substation, and an electromagnetic wave generation source arranged outside the factory, the power plant, or the substation.

In addition, the electromagnetic wave to be targeted in the present disclosure includes an electromagnetic wave generated by partial discharge, an electromagnetic wave generated by a current flowing through the cable at the time of abnormality, and an electromagnetic wave generated by a surge voltage inside the semiconductor device.

An electromagnetic wave detection device, according to the present disclosure, is a device that detects a partial discharge, an abnormal current or an abnormal voltage generated in a cable, or a surge voltage generated by an abnormality inside a semiconductor device with respect to the electromagnetic wave generation source 100 described above.

Note that a high-frequency signal based on a high-frequency electromagnetic wave generated by partial discharge, a high-frequency signal based on a high-frequency electromagnetic wave generated by a current flowing through the cable at the time of abnormality, and a high-frequency signal based on a high-frequency electromagnetic wave generated by a surge voltage inside the semiconductor device are included in the high-frequency signal at the time of abnormality.

In the following description, when it is not necessary to distinguish and describe the electromagnetic wave generation sources (a) to (f) described above, the electromagnetic wave generation source 100 is used, and the electromagnetic wave generation source 100 is any one of the electromagnetic wave generation sources (a) to (e) and the similar electromagnetic wave generation sources as the electromagnetic wave generation sources (a) to (e).

### [First Space A]

The first space A is a space in which the electromagnetic wave generation source 100 is disposed.

The first space A targets, for example, the following (a) to (e).

(a) In an electronic device, a space that is separated by using, as a partition plate 200, a conductor plate, a radio wave absorption sheet that hinders propagation of an electromagnetic wave, a conductor such as a ground surface of a printed circuit board on which a semiconductor element is mounted in a case where a semiconductor device serves as an electromagnetic wave generation source, or the like, and has an electromagnetic wave generation source 100 disposed therein.

(b) A space inside an electromagnetic shield that covers a semiconductor device.

(c) In a factory, a power plant, or a substation in which the electromagnetic wave generation source 100 is disposed of, a chamber in which the electromagnetic wave generation source 100 is disposed. The partition plate 200 partitions one chamber, and is, for example, a wall.

(d) A closed space in which the electromagnetic wave generation source 100 is disposed of. The partition plate 200 is a part of, for example, a housing or the like for forming the closed space.

Note that, since a metal cable such as a power line or a communication line is drawn out from the housing from the inside of the electronic device toward the outside of the electronic device, an electromagnetic wave may enter the inside of the electronic device from the outside of the electronic device in a manner superimposed on the cable. Even in such a case, the present disclosure provides a housing constituting a closed space.

(e) An open space in which the electromagnetic wave generation source 100 is disposed. The open space may be a space into which a part of the electromagnetic wave from other than the electromagnetic wave generation source 100 enters. The partition plate 200 is a plate that partitions the second space B where the electromagnetic wave generation source 100 is not disposed and attenuates the propagation of the electromagnetic wave from the first space A to the second space B.

In short, the first space A is a space that includes the above-described (a) to (e), is partitioned by the partition plate 200 that attenuates the propagation of the electromagnetic wave from the first space A to the second space B and has the electromagnetic wave generation source 100 disposed therein.

### [Second Space B]

The second space B is a space that is partitioned from the first space A by the partition plate 200, and has no electromagnetic wave generation source therein.

The second space B targets, for example, the following (a) to (e).

(a) In an electronic device, a space that has no electromagnetic wave generation source therein, and is separated from the first space A by using, as a partition plate 200, a conductor plate, a radio wave absorption sheet that hinders propagation of an electromagnetic wave, a conductor such as a ground surface of a printed circuit board on which a semiconductor element is mounted in a case where a semiconductor device serves as an electromagnetic wave generation source, or the like.

(b) A space outside the electromagnetic shield that covers the semiconductor device.

(c) In a factory, a power plant, or a substation in which the electromagnetic wave generation source 100 is disposed of, one chamber that is separated from the first space A by the partition plate 200 and has no electromagnetic wave generation source therein.

(d) A closed space that is separated from the first space A by the partition plate 200 and has no electromagnetic wave generation source 100 therein.

(e) An open space that is separated from the first space A by the partition plate 200 and has no electromagnetic wave generation source 100 therein. The open space may be a space into which a part of the electromagnetic wave from other than the electromagnetic wave generation source 100 enters.

In short, the second space B is a space that includes the above-described (a) to (e), is partitioned by the partition plate 200 that attenuates the propagation of the electromagnetic wave from the first space A to the second space B, and has no electromagnetic wave generation source 100 therein.

### [Partition Plate 200]

The partition plate 200 targets, for example, the following (a) to (f).

The partition plate 200 attenuates the propagation of the electromagnetic wave from the first space A to the second space B.

### <<Target>>

(a) A conductor such as a conductor plate, a radio wave absorbing sheet, or a ground surface of a printed circuit board in an electronic device.

(b) Mesh structure composed of punching metal and wire.

(c) A conductor plate such as a metal plate, a metal plate partially having a hole, or a metal plate partially having a dielectric containing air.

(d) A dielectric having a conductor at least partially.

For example, the dielectric plated with a conductor, the conductor coated with a dielectric containing a resin, and the dielectric and the conductor separated and fitted with a screw, a bolt, an adhesive, or the like.

(e) An electromagnetic shield covering a semiconductor device.

For example, the electromagnetic shield directly soldered and connected to the printed circuit board, or the shield plate and the printed circuit board connected via an on-board contact, an on-board clip, or the like.

(f) A shield that attenuates the propagation of an electromagnetic wave and partitions the first space A and the second space B in a factory, a power plant, or a substation.

### <<Shape>>

Flat plate.
Curved plate.
A plate-shaped body bent a plurality of times.
   <<Partition Plate with Plurality of Holes Opened>>
Partition plate 200 having only holes of a cut-off frequency or less

The size of the hole corresponding to the cutoff frequency varies depending on the shape of the hole such as a circle or a square, but is generally λ/4 or less with respect to the wavelength λ at the maximum value of the frequency of the electromagnetic wave generation source 100.

For example, when the frequency of the electromagnetic wave generated at the time of abnormality is 300 MHz, since the wavelength λ is 1 m, the partition plate 200 has only holes with a diameter of λ/4=0.25 m or less.
The partition plate 200 having a hole of a cutoff frequency or higher at which the cutoff frequency electromagnetic wave is hardly attenuated.

When the partition plate is used for a housing of an electronic device, since a plurality of conductors is generally used inside the electronic device, the electromagnetic wave generated at the time of abnormality has a mechanism that forms a complicated propagation path of the electromagnetic wave due to multiple reflections by the plurality of conductors, the electromagnetic wave is less likely to propagate outside the housing of the electronic device, and the partition plate having a hole with a cutoff frequency or higher is also a target of the partition plate 200 of the present disclosure since propagation of the electromagnetic wave from the first space A to the second space B is attenuated.

### <<Thickness of Partition Plate>>

When the partition plate 200 is a conductor plate,
although it is necessary to consider the skin effect, the conductor plate is a target of the partition plate 200 of the present disclosure having sufficient shield characteristics unless the conductor plate has an extremely thin thickness of several μm or less.

Since a metal plate used in a general electronic device is not several μm or less, the metal plate having any thickness is a target of the partition plate 200 of the present disclosure.

Next, the disturbance noise with respect to the electromagnetic wave generated at the time of abnormality of the electromagnetic wave generation source 100 will be described.

The disturbance noise entering the first space A and the second space B is, for example, the following (a) to (d).

(a) Electromagnetic waves generated from televisions, radios, mobile phones, and the like.

(b) Electromagnetic waves generated in nature such as lightning and static electricity.

(c) An electromagnetic wave generated inside the electronic device and coming from a source other than the electromagnetic wave generation source 100.

(d) An electromagnetic wave generated outside the electronic device and propagating through a power supply line and a communication line drawn into the electronic device.

In short, all electromagnetic waves other than the electromagnetic wave generation source 100 for which abnormality detection is performed are disturbance noises.

When the frequency of the disturbance noise is the same as the frequency of the electromagnetic wave generated at the time of abnormality of the electromagnetic wave generation source 100, it is difficult to distinguish between the electromagnetic wave generated at the time of abnormality and the disturbance noise.

That is, false detection and false detection are likely to occur in an environment where disturbance noise is large.

The electromagnetic wave generated at the time of abnormality of the electromagnetic wave generation source 100 and the disturbance noise can be distinguished from each other by a signal-to-noise ratio (S/N ratio) that is a ratio of the disturbance noise N to the electromagnetic wave S generated at the time of abnormality of the electromagnetic wave generation source 100.

That is, the decrease in the received voltage and current when the electromagnetic wave S generated at the time of abnormality of the electromagnetic wave generation source is detected can be suppressed, the S/N ratio can be increased, and false detection and false detection can be eliminated.

The electromagnetic wave detection device according to the present disclosure can increase the S/N ratio.

Hereinafter, the electromagnetic wave observation unit 10, the detection unit 20, and the measurement unit 30, which are components of the electromagnetic wave detection device according to the first embodiment, will be described.

The electromagnetic wave observation unit 10 includes a metal wire having a penetrating portion 11 that penetrates a through hole 200A formed in the partition plate 200 while being separated from a peripheral wall of the through hole 200A, a protruding portion 12 that protrudes from the penetrating portion 11 to the first space A and receives the electromagnetic wave from the electromagnetic wave generation source 100, and an extending portion 13 that extends from the penetrating portion 11 to the second space B. One end portion of the electromagnetic wave observation unit 10 located on the second space B side is connected to a ground point 300, which is a ground potential.

As a result, the metal wire 10 reaches the ground point from the protruding portion 12 via the penetrating portion 11 and the extending portion 13.

Note that it is desirable to provide the ground point 300 on the conductor portion of the partition plate 200 as the ground point of the metal wire 10.

This is because a potential difference is generated between the metal wire 10 and the partition plate 200 by the electromagnetic wave generation source 100, so that a high-frequency current or voltage generated by the potential difference can be detected.

When the ground point is provided on the partition plate 200 in this manner, a path along which an electric current flow is formed between the protruding portion 12 and the partition plate 200.

In addition, when the partition plate 200 is a dielectric having a conductor at least partially, the ground point 300 of the partition plate 200 is electrically conducted with the conductor.

Even in a case where the partition plate 200 is a dielectric having a conductor at least partially and targets a device that is an electric device or an electronic device having the electromagnetic wave generation source 100, there is electrical conduction between the conductor of the partition plate 200 and a metal portion of a housing of the device that is the electric device or the electronic device.

In the following description, the electromagnetic wave observation unit 10 will be described as a metal wire 10.

In the first embodiment, the partition plate 200 will be described as a conductor plate 200 in order to avoid complications in the description. However, the partition plate 200 is not limited to the conductor plate, and any of the partition plates 200 exemplified above can be applied.

The metal wire 10 is a covered wire covered with an insulator or a bare wire.

The use of the covered wire can prevent destruction, malfunction, short-circuit, or ground fault of the electronic device due to contact with the electronic device due to an unexpected accident. When there is no possibility of contact with the electronic device, a large current and a large voltage are not applied to the metal wire 10, so that the bare wire may be used absolutely.

Since a large current does not flow through the metal wire 10 and a large voltage is not applied between the metal wire 10 and the conductor plate 200, it is not necessary to consider the rated current and the rated voltage, and it is desirable to use a soft and thin covered wire which is easy to route.

For example, when the metal wire 10 having a diameter of 1 mm or less is used, it is soft and can be easily routed. However, in a case where it is desired to fix the shape and in a case where it is desired to maintain the shape by the metal wire 10 itself, it is preferable to use a metal wire having a large diameter that is hardly deformed or a metal wire having a coating which is hardly deformed.

The through hole 200A of the conductor plate 200 has a diameter equal to or larger than the thickness of the metal wire 10.

The through hole 200A is not necessarily located at the center of the conductor plate 200, and may be located at the end of the conductor plate 200.

The metal wire 10 has a penetrating portion 11, a protruding portion 12, and an extending portion 13.

The penetrating portion 11 of the metal wire 10 penetrates the through hole 200A of the conductor plate 200 so as not to contact the through hole and is laid.

The protruding portion 12 of the metal wire 10 is laid so as not to be electrically connected to the conductor plate 200, that is, so as not to be in contact with the surface of the conductor plate 200 at a distance.

The protruding portion 12 of the metal wire 10 functions as a receiving unit that receives the electromagnetic wave from the electromagnetic wave generation source 100 disposed in the first space A.

The protruding portion 12 of the metal wire 10 may have a structure protruding even a little from the through hole 200A, and may protrude even by 1 mm, for example.

By using the metal wire 10 having the protruding portion 12, the S/N ratio can be improved as compared with the case where the metal wire 10 is not provided.

Since the frequency of the electromagnetic wave due to the partial discharge, the frequency of the electromagnetic wave when abnormality detection of the cable is performed, and the frequency of the electromagnetic wave when abnormality detection of the inside of the semiconductor device is performed are within the frequency range of 1 MHz to 1 GHz, the length of the protruding portion 12 of the metal wire 10 is a length corresponding to the electromagnetic wave having a frequency of 1 MHz to 1 GHz.

In order to resonate, for an electromagnetic wave having a frequency of 1 GHz or more, the length of the protruding portion 12 of the metal wire 10 is desirably 0.15 m or less, which is ½ wavelength or more. For an electromagnetic wave having a frequency of 1 MHz or less, the length of the protruding portion 12 of the metal wire 10 is desirably 150 m or more, which is ½ wavelength or more.

However, since the wavelength can be shortened by a circuit element to be described later, the length can be made shorter than the above length. For example, even at 1 MHz, the length can be made 1.5 m or less by using a coil using a magnetic body for the circuit element.

In addition, when the metal wire can be brought close to the discharge source, it is not necessary to cause resonance, so that the metal wire can be shortened. When the discharge source and the protruding portion are electrically coupled to each other, if the protruding portion protrudes by a distance shorter than ½ wavelength, for example, even 1 mm, partial discharge can also be detected at 1 MHz and 1 GHz.

It is desirable to lay the protruding portion 12 of the metal wire 10 close to the electromagnetic wave generation source 100, specifically, so that the shortest distance from the electromagnetic wave generation source 100 to the metal wire 10 is within 0.3 m.

By laying the protruding portion 12 of the metal wire 10 within 0.3 m, even if the electromagnetic wave at the time of abnormality from the electromagnetic wave generation source 100 is weak, the received signal strength is good, and a high S/N ratio can be obtained.

In order to receive the electromagnetic wave of the electromagnetic wave generation source 100, the protruding portion 12 of the metal wire 10 desirably has a long length running in parallel with the electromagnetic wave generation source 100.

In the case of monitoring an abnormal current or an abnormal voltage flowing through the cable that is the electromagnetic wave generation source 100, the distance between the electromagnetic wave receiving unit in the protruding portion 12 and the cable is set to 10 mm or less, and desirably 1 mm or less, although the distance also varies depending on the intensity and frequency of the high-frequency signal generated at the time of abnormality.

As a result, abnormality detection of the cable can be performed at a high S/N ratio.

In particular, it is desirable to dispose of the electromagnetic wave receiving unit in the protruding portion 12 in the vicinity of a cable to which a high voltage is applied, a cable through which a large current flow, a cable to which vibration is likely to be applied structurally, and a connector.

In the case of monitoring the surge voltage inside the semiconductor device covered with the electromagnetic shield, which is the electromagnetic wave generation source 100, the protruding portion 12 of the metal wire 10 is an extremely thin metal wire such as a polyurethane copper wire. The protruding portion 12 is disposed inside the electromagnetic shield covering the semiconductor device.

As a result, the abnormality due to the surge voltage inside the semiconductor device covered with the electromagnetic shield can be observed from the outside of the electromagnetic shield by the protruding portion 12 receiving the electromagnetic wave due to the surge voltage and the current based on the received electromagnetic wave flowing through the penetrating portion 11 and the extending portion 13.

When the plurality of electromagnetic wave generation sources 100 having a short distance between the electromagnetic wave generation sources 100 are arranged in the first space A, the protruding portion 12 of the metal wire 10 may be disposed near the plurality of electromagnetic wave generation sources 100. The protruding portion 12 of the metal wire 10 may detect and observe the electromagnetic waves from the plurality of electromagnetic wave generation sources 100.

In this case, among the plurality of electromagnetic wave generation sources 100, it is difficult to estimate the accurate position of the electromagnetic wave generation source 100 in which the abnormality has occurred. Still it is possible to detect and observe the abnormality with respect to the plurality of electromagnetic wave generation sources 100.

The extending portion 13 of the metal wire 10 is laid so as not to be conducted with the conductor plate 200, that is, so as not to be in contact with the back surface of the conductor plate 200 at a distance.

The extending portion 13 of the metal wire 10 has a contact point electrically connected to the ground point 300 of the conductor plate 200 at one end portion.

The extending portion 13 of the metal wire 10 has a constant length from the penetrating portion 11 to the contact point, allowing a current based on an electromagnetic wave received by the protruding portion 12 to flow to the ground point 300 via the contact point, and functions as an observation unit that detects a high-frequency signal at the time of abnormality by a flowing current or an electromagnetic wave emitted by the flowing current.

When the length of the extending portion 13 of the metal wire 10 is long, in a case where the frequency of the electromagnetic wave at the time of abnormality from the electromagnetic wave generation source 100 is high, the current due to the electromagnetic wave at the time of abnormality from the electromagnetic wave generation source 100 received by the protruding portion 12 hardly flows through the extending portion 13 due to the residual inductance (about 1 nH/mm although it varies depending on the thickness and the material) of the extending portion 13 of the metal wire 10. Therefore, it is desirable to shorten the length of the metal wire 10.

In a case where an antenna that receives the electromagnetic wave emitted from the extending portion 13 is used for the detection unit 20, if the routing of the extending portion 13 is shortened, the antenna hardly receives the electromagnetic wave from the extending portion 13. Therefore, it is desirable to set the length from the penetrating portion 11 to the contact point to 0.1 m or more.

On the other hand, in a case where a current sensor such as a current probe (CT: Current Transformer) that detects the current flowing through the extending portion 13 is used for the detection unit 20, the current sensor may be attached to the extending portion 13, and the length of the extending portion may be the shortest, that is, the length from the penetrating portion 11 to the contact point may be the length for attaching the current sensor.

The contact point at one end portion of the extending portion 13 of the metal wire 10 may be any contact point as long as the contact point does not electrically disconnect the ground point 300 in the conductor plate 200 and does not corrode within the use period.

For example, in the case of joining by soldering and welding, bonding by copper tape, joining by a conductive adhesive, and joining by a crimping tool, the contact point is a joining portion electrically connected to the ground point 300 at one end portion of the extending portion 13.

In the case of joining by a bolt and a nut, the contact point is a connection terminal through which the bolt penetrates, which is electrically connected to the ground point 300 at one end portion of the extending portion 13.

In the case of joining by a connector, the contact point is a connector electrically connected to the ground point 300 at one end portion of the extending portion 13.

The distance between the peripheral surface of the penetrating portion 11 and the peripheral wall surface of the through hole 200A, the distance between the peripheral surface of the protruding portion 12 and the surface of the conductor plate 200, and the distance between the peripheral surface of the extending portion 13 and the back surface of the conductor plate 200 are each 5 mm or more, and preferably 10 mm or more.

By separating the metal wire 10 from the conductor plate 200 by 5 mm or more, a current based on the electromagnetic wave received by the protruding portion 12 due to a parasitic component generated between the metal wire 10 and the conductor plate 200 is suppressed from flowing through the conductor plate 200.

That is, it is possible to suppress a decrease in the current based on the electromagnetic wave received by the protruding portion 12 and to prevent a decrease in the S/N ratio.

The distance between the peripheral surface of the penetrating portion 11 and the peripheral wall surface of the through hole 200A is preferably set so that a covered wire is used as the metal wire 10, and the thickness of the insulator of the covered wire is 1 mm or more.

The detection unit 20 is disposed in the second space B, detects the electromagnetic wave detected and observed by the electromagnetic wave observation unit 10, and outputs the electromagnetic wave as an electromagnetic wave detection signal.

The detection unit 20 is an electromagnetic wave detection sensor that receives a high-frequency signal in which a current due to an electromagnetic wave at the time of abnormality from the electromagnetic wave generation source 100 is superimposed on the metal wire 10, detects the high-frequency signal by the electromagnetic wave observation unit 10, and detects the observed electromagnetic wave at the time of abnormality in a non-contact state with respect to the metal wire 10.

The high-frequency signal referred to herein is a signal based on any of a current and a voltage due to the electromagnetic wave at the time of abnormality superimposed on the metal wire 10, and an electric field and a magnetic field generated with the current superimposed on the metal wire 10.

The electromagnetic wave detection sensor is an electromagnetic field sensor including an antenna such as a biconical antenna, or a current sensor.

However, the detection unit 20 is not limited to the antenna and the current sensor.

Note that the antenna and the current sensor function as detecting units in the detection unit 20.

For example, a measurement metal wire connected to a measuring instrument constituting the measurement unit 30 may run in parallel with the extending portion 13 of the metal wire 10, and the measurement metal wire may be used as a detecting unit in the detection unit 20. In this case, a current in which a high-frequency signal based on an electromagnetic wave emitted from the metal wire is superimposed on the measurement metal wire flows through the measurement metal wire.

In addition, a sensor that observes electrons, a film that reacts to a high-frequency signal, a magnetic sheet that converts a high-frequency signal into heat, or the like, which indirectly detects a high-frequency signal, may be used as the detecting unit in the detection unit 20.

When the frequency of the high-frequency signal due to the electromagnetic wave at the time of abnormality superimposed on the metal wire 10 is as low as 1 MHz or less, a Hall effect sensor or an element using the giant magnetoresistance (GMR) effect or the tunnel magnetoresistance (TMR) effect may be used for the detection unit 20.

By using a non-contact sensor such as an antenna or a current sensor that is not in contact with the extending portion 13 of the metal wire 10 and detects a high-frequency signal by the extending portion 13 as the detection unit 20, since there is no direct electrical connection between the metal wire 10 and the non-contact sensor, the metal wire 10 has no direct electrical connection with various circuits in the electromagnetic wave detection device, and a short-circuit accident and a ground fault due to a path from the electromagnetic wave generation source 100 to a power source (not illustrated) of the electromagnetic wave detection device via the metal wire 10 and the non-contact sensor of the detection unit 20 can be prevented.

Signal frequency bands used in televisions, radios, mobile phones, and the like have high signal strength.

Therefore, the detection unit 20 can detect the electromagnetic wave at the time of abnormality from the electromagnetic wave generation source 100 with a high S/N ratio with respect to the high-frequency signal based on the electromagnetic wave at the time of abnormality from the electromagnetic wave generation source 100 by providing a filter, particularly a band pass filter, in the output unit and cutting the frequency band of the signal used in the television, the radio, the mobile phone, and the like.

As a result, false detection due to disturbance noise can be reduced.

Note that the filter may be provided not in the output unit of the detection unit 20 but in the input unit of the measurement unit 30.

The measurement unit 30 is a measuring instrument that monitors an abnormality in the electromagnetic wave generation source 100 by receiving the electromagnetic wave detection signal from the detection unit 20 via the coaxial cable 40, monitoring the input electromagnetic wave detection signal, and extracting the electromagnetic wave at the time of abnormality from the electromagnetic wave generation source 100.

When thermal disturbance noise with high signal intensity is superimposed on the electromagnetic wave detection signal from the detection unit 20, the measurement unit 30 can detect the electromagnetic wave at the time of abnormality from the electromagnetic wave generation source 100 with a high S/N ratio with respect to the high-frequency signal based on the electromagnetic wave at the time of abnormality from the electromagnetic wave generation source 100 by providing a preamplifier in the input unit and amplifying the electromagnetic wave detection signal from the detection unit 20.

As a result, false detection due to disturbance noise can be reduced.

When the timing at which the disturbance noise is detected is known, the measurement unit 30 may receive the timing at which the disturbance noise is detected, perform signal processing on the electromagnetic wave detection signal received from the detection unit 20 at the timing, and reduce the disturbance noise.

In this case, the S/N ratio is improved by reducing the disturbance noise, and as a result, false detection due to the disturbance noise can be reduced.

In a case where the timing at which the disturbance noise is detected is known, for example, when the device including the electromagnetic wave generation source 100 is driven by a commercial power supply, the disturbance noise is generated at the timing proportional to the commercial power supply from the electromagnetic wave generation source 100.

In addition, an electromagnetic wave, that is, disturbance noise is generated from the electromagnetic wave generation source 100 at a timing proportional to a specific frequency according to the specific frequency, for example, the operation frequency of the CPU in a device including the electromagnetic wave generation source 100 by the signal in the device.

When the device including the electromagnetic wave generation source 100 is an electric discharge machine, an electromagnetic wave, that is, disturbance noise is generated from the electromagnetic wave generation source 100 at the timing when the electric discharge machine discharges.

In short, since the frequency characteristic and the periodicity of the disturbance noise generated from the electromagnetic wave generation source 100 can be grasped as the environmental noise in the case exemplified above, the measurement unit 30 can remove the environmental noise by signal processing by inputting the grasped information on the environmental noise to the measurement unit 30, and false detection due to the environment noise can be reduced.

The measurement unit 30 is selected in accordance with the characteristics of the high-frequency signal in which the current due to the electromagnetic wave at the time of abnormality from the electromagnetic wave generation source 100 is superimposed on the metal wire 10.

The measurement unit 30 is a measuring instrument that acquires a time waveform such as an oscilloscope, a measuring instrument that measures frequency characteristics such as a spectrum analyzer, or a measuring instrument that measures a time waveform of a frequency of bandwidth in real-time such as a real-time spectrum analyzer.

The measuring instrument that acquires the time waveform is suitable for measuring and detecting the electromagnetic wave due to the partial discharge at the initial stage because the partial discharge at the initial stage due to deterioration over time of the electronic device is intermittent.

Since the measuring instrument that measures the frequency characteristics has a wide dynamic range, the measuring instrument is suitable for measuring and detecting an electromagnetic wave that continuously and repeatedly provides the same waveform, that is, an electromagnetic wave with high reproducibility.

In the case of using a spectrum analyzer, in order to prevent missing, it is preferable to measure by performing several frequency sweeps in the Max Hold condition to obtain the maximum value at each frequency.

A measuring instrument that measures a time waveform of a frequency in real time is suitable for measuring and detecting an electromagnetic wave due to partial discharge when a frequency band at the time of discharge in the partial discharge can be predicted.

A real-time spectrum analyzer can measure a time waveform of a frequency of a desired bandwidth in real-time, and is excellent at measuring various signals, such as a pulsed signal and a continuous signal.

In a case where only signal strength is required and in a case where only a specific frequency signal needs to be acquired, the measurement unit 30 may be a power meter (power meter), a peak hold circuit, or a simpler measuring instrument of an electric circuit combining an A/D converter and a comparator.

Next, abnormality detection in the electromagnetic wave detection device according to the first embodiment will be described.

The protruding portion 12 of the metal wire 10 disposed of in proximity to the electromagnetic wave generation source 100 disposed of in the first space A always receives the electromagnetic wave emitted from the electromagnetic wave generation source 100, and monitors and observes the electromagnetic wave.

The protruding portion 12 that has received the electromagnetic wave emitted from the electromagnetic wave generation source 100 generates a current corresponding to the received electromagnetic wave, and the current flows from the protruding portion 12 to the ground point 300 of the conductor plate 200 via the penetrating portion 11, the extending portion 13, and the contact point.

The detection unit 20 continuously monitors the current flowing through the extending portion 13 of the metal wire 10, and outputs an electromagnetic wave detection signal, which is a result of monitoring by the detection unit 20 via the coaxial cable 40, to the measurement unit 30.

The measurement unit 30 monitors and measures the electromagnetic wave detection signal from the detection unit 20, and displays the measurement result on the display unit.

When the electromagnetic wave at the time of abnormality due to partial discharge or the like is superimposed on the electromagnetic wave emitted from the electromagnetic wave generation source 100, the measurement result by the measurement unit 30 indicates a result of exceeding the set threshold.

An alarm may be issued when a measurement result by the measurement unit 30 exceeds a set threshold.

A case where the electromagnetic wave detection device, according to the first embodiment, performs abnormality detection based on partial discharge due to deterioration over time of an insulator will be described.

Since the partial discharge itself does not occur between the electrodes, the partial discharge is hardly affected by the impedance between the electrodes.

However, as the partial discharge progresses, the impedance between the electrodes decreases, and spark discharge or flashover, which is discharge between the electrodes, occurs.

If spark discharge or flashover occurs between the electrodes, a short-circuit accident occurs. In addition, if spark discharge or flashover occurs between the electrode and the ground, it is a ground fault.

There is a risk that a spark is generated due to a short-circuit accident and a ground fault, and the spark is ignited by an insulator or the like, leading to a serious accident.

Even when the circuit breaker operates normally, the entire device including peripheral devices stops, and thus serious damage is likely to occur.

Furthermore, there is a risk of causing malfunction or destruction of an external electronic device connected to the cable.

In the electromagnetic wave detection device according to the first embodiment, it is possible to find a risk at the stage of partial discharge in the initial stage of deterioration, and to prevent a major accident in advance.

In addition, in an environment where a large voltage and a large current flow in the electromagnetic wave generation source 100 such as a distribution board or an air conditioner, an electric field or a magnetic field having a strong intensity that periodically changes depending on an operation frequency of a power source of the distribution board or the air conditioner is generated.

If the protruding portion 12 of the metal wire 10 is disposed of in an environment where this strong electric field or magnetic field is generated, and charges are accumulated in the protruding portion 12, Lorentz force acts on the protruding portion 12 by the periodically changing electric field or magnetic field, the protruding portion 12 repeats expansion and contraction, and metal fatigue may occur in the protruding portion 12.

Since the metal wire 10 in the electromagnetic wave detection device according to the first embodiment is connected to the ground point 300 of the conductor plate 200 at the end portion of the extending portion 13, electric charge flows out to the ground point 330, so that charging in the protruding portion 12 is prevented, and electric charge hardly accumulates in the protruding portion 12. Therefore, a Lorentz force hardly acts on the protruding portion 12.

As a result of comparing the metal wire 10 with the metal wire 10 in an electrically floating state, the Lorentz force acting on the protruding portion 12 connecting the end portion of the extending portion 13 of the metal wire 10 to the ground point 300 was 1/10 or less.

That is, the metal wire 10 in the first embodiment has the advantage that the laid state is maintained for a long period of time.

As described above, the electromagnetic wave detection device according to the first embodiment is an electromagnetic wave detection device that detects an electromagnetic wave from the electromagnetic wave generation source 100 in the second space B partitioned from the first space A in which the electromagnetic wave generation source 100 is disposed by the partition plate 200 that attenuates propagation of the electromagnetic wave, the electromagnetic wave detection device including the electromagnetic wave observation unit 10 including a metal wire having: the penetrating portion 11 that penetrates a through hole 200A formed in the partition plate 200 while being separated from the peripheral wall of the through hole 200A; the protruding portion 12 that protrudes from the penetrating portion 11 to the first space A and receives the electromagnetic wave from the electromagnetic wave generation source 100; and the extending portion 13 that extends from the penetrating portion 11 to the second space, in which one end portion located on the second space B side is connected to the ground point 300. Therefore, by using the electromagnetic wave observation unit 10 having a simple structure, the detection of the electromagnetic wave from the electromagnetic wave generation source 100 disposed in the first space A can be performed in the second space B.

In addition, since the one-end portion of the electromagnetic wave observation unit 10 located on the second space B side is connected to the ground point 300, it is possible to prevent the metal wire from being charged, and to maintain the metal wire in the laid state for a long period.

Furthermore, by using the metal wire with the protruding portion 12, the S/N ratio can be improved as compared with the case where there is no metal wire.

Since the metal wire in the electromagnetic wave observation unit 10 is laid at a distance of 5 mm or more, preferably 10 mm or more, from the front and back surfaces of the conductor plate 200 and the peripheral wall surface of the through hole 200A, it is possible to suppress a current based on the electromagnetic wave received by the protruding portion 12 from flowing through the conductor plate 200 due to a parasitic component generated between the metal wire and the conductor plate 200 and to suppress the current from decreasing, so that it is possible to enhance receiver sensitivity and prevent a decrease in the S/N ratio.

Since the metal wire in the electromagnetic wave observation unit 10 protrudes from the through hole 200A formed in the conductor plate 200 by 1 mm or more, and the shortest distance from the electromagnetic wave generation source 100 to the metal wire 10 is within 0.3 m, even if the electromagnetic wave at the time of abnormality from the electromagnetic wave generation source 100 is weak, the received signal strength is good, and a high S/N ratio can be obtained.

When the electromagnetic wave generation source 100 is a cable, since the distance between the electromagnetic wave receiving unit in the protruding portion 12 of the metal wire 10 and the cable or the electric wire of the electromagnetic shield wire is 10 mm or less, a high S/N ratio can be obtained.

In the case of the inside of the semiconductor device covered with the electromagnetic shield which is the electromagnetic wave generation source 100, the electromagnetic wave receiving unit in the protruding portion 12 of the metal wire in the electromagnetic wave observation unit 10 is an extra-fine metal wire such as a polyurethane copper wire, and the protruding portion 12 is disposed inside the electromagnetic shield covering the semiconductor device, so that the received signal strength is good and a high S/N ratio can be obtained.

When a non-contact sensor such as an antenna or a current sensor is used for the detection unit 20, since there is no direct electrical connection between the extending portion 13 of the metal wire 10 and the non-contact sensor, the metal wire in the electromagnetic wave observation unit is not directly electrically connected to various circuits in the electromagnetic wave detection device, and a short-circuit accident and a ground fault due to a path from the electromagnetic wave generation source 100 to the power supply of the electromagnetic wave detection device via the metal wire and the non-contact sensor of the detection unit 20 can be prevented.

### Second Embodiment

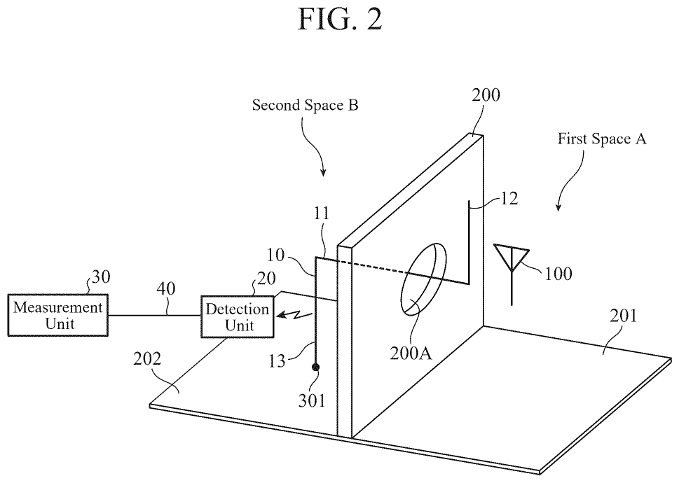

An electromagnetic wave detection device according to a second embodiment will be described with reference to FIG. 2.

The electromagnetic wave detection device according to the second embodiment is different from the electromagnetic wave detection device according to the first embodiment in terms of a ground point at which a contact point provided at one end portion of the extending portion 13 of the metal wire in the electromagnetic wave observation unit 10 is connected, and is the same in other points.

In FIG. 2, the same reference numerals as those in FIG. 1 denote the same or corresponding parts.

In the following description, the electromagnetic wave observation unit will be described as a metal wire 10.

In the conductor plate 200 having the through hole 200A, which is a partition plate that partitions the first space A and the second space B, a ground point 301 is provided in a second conductor plate 202 continuously formed on the second space B side.

A contact point provided at one end portion of the extending portion 13 of the metal wire 10 is electrically connected to the ground point 301 of the second conductor plate 202.

The metal wire 10 forms a path along which an electric current flow from the protruding portion 12 to the ground point 301 in the second conductor plate 202 via the penetrating portion 11 and the extending portion 13.

An electromagnetic wave detection device according to the second embodiment configured as described above also has the same effect as the electromagnetic wave detection device according to the first embodiment.

The second conductor plate 202 may be an integrally formed conductor plate bent at a right angle from one side of the conductor plate 200, or a separate conductor plate joined to and electrically connected to one side of the conductor plate 200.

The direct current resistance between the conductor plate 200 and the second conductor plate 202 is 10Ω or less and close to 0Ω.

### Third Embodiment

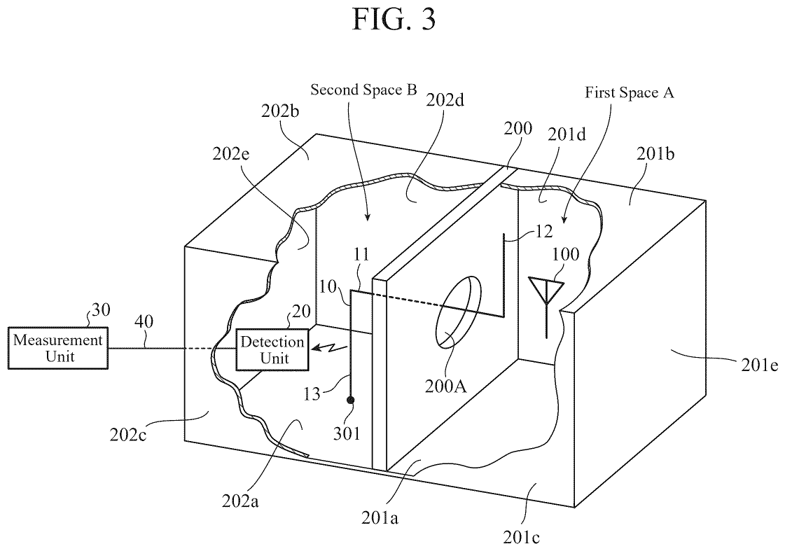

An electromagnetic wave detection device according to a third embodiment will be described with reference to FIG. 3.

The electromagnetic wave detection device according to the third embodiment is different from the electromagnetic wave detection device according to the first embodiment in that, in the electromagnetic wave detection device according to the first embodiment, the first space A and the second space B are surrounded by a conductor, and the first space A and the second space B are spaces electrically shielded by a conductor plate, and in terms of the ground point 301 at which a contact point provided at one-end portion of the extending portion 13 of the metal wire 10 is connected as in the electromagnetic wave detection device according to the second embodiment, and is the same in other points.

In FIG. 3, the same reference numerals as those in FIGS. 1 and 2 denote the same or corresponding parts.

In the following description, the electromagnetic wave observation unit 10 will be described as a metal wire 10.

The first space A is a space surrounded by six conductor plates 200, 201a to 201e including the conductor plate 200 having the through hole 200A, which is a partition plate.

The second space B is a space surrounded by six conductor plates 200, 202a to 202e including the conductor plate 200 having the through hole 200A, which is a partition plate.

That is, the first space A and the second space B are partitioned by the conductor plate 200 having the through hole 200A, and the first space A and the second space B are completely surrounded by the conductor plate except for the through hole 200A.

A contact point provided at one end portion of the extending portion 13 of the metal wire 10 is electrically connected to the ground point 301 of a second conductor plate 202a.

The metal wire 10 forms a path along which electrical current flows from the protruding portion 12 to the ground point 301 in the second conductor plate 202a via the penetrating portion 11 and the extending portion 13.

The electromagnetic wave detection sensor of the electromagnetic field sensor or the current sensor including an antenna such as a biconical antenna in the detection unit 20 is disposed in the second space in proximity to the extending portion 13 of the metal wire 10, detects the electromagnetic wave detected and observed by the electromagnetic wave observation unit 10, and the detection unit 20 outputs the electromagnetic wave as the electromagnetic wave detection signal.

The measurement unit 30 is disposed in another space different from the first space A and the second space B, and the electromagnetic wave detection signal from the detection unit 20 is input thereto via the coaxial cable 40.

Since the first space A and the second space B are completely surrounded by the conductor plate except for the through hole 200A, the electromagnetic wave from the electromagnetic wave generation source 100 disposed in the first space A has very weak intensity.

When the diameter of the through hole 200A is the cutoff frequency in the electromagnetic wave at the time of abnormality from the electromagnetic wave generation source 100, although the evanescent wave leaks from the first space A to the second space B through the through hole 200A, the first space A and the second space B are regarded as shielded spaces.

In addition, when the diameter of the through hole 200A is 1/10 wavelength or less of the cutoff frequency of the electromagnetic wave at the time of abnormality from the electromagnetic wave generation source 100, the first space A and the second space B are regarded as completely shielded spaces.

As described above, even if the electromagnetic wave from the electromagnetic wave generation source 100 from the first space A to the second space B is very weak or completely cut off, the electromagnetic wave detection device according to the third embodiment can detect and observe the electromagnetic wave from the electromagnetic wave generation source 100 in the second space B since the protruding portion 12 of the metal wire 10 receives the electromagnetic wave of the electromagnetic wave generation source 100 without decreasing the intensity of the electromagnetic wave, and the current corresponding to the received electromagnetic wave flows from the protruding portion 12 to the extending portion 13 through the penetrating portion 11.

The electromagnetic wave detection device according to the third embodiment configured as described above also has the same effect as the electromagnetic wave detection device according to the first embodiment.

Since the first space A in which the electromagnetic wave generation source 100 is disposed is a space electrically shielded by the conductor plate, the electromagnetic wave from the electromagnetic wave generation source 100 is multiple-reflected by the conductor plate constituting the first space A and superimposed on the protruding portion 12 of the metal wire 10, so that the receiver sensitivity of the protruding portion 12 of the metal wire 10 is increased.

Although both the first space A and the second space B are closed spaces, the first space A and the second space B are not necessarily closed spaces, and may be open spaces into which a part of the electromagnetic wave can enter.

### Fourth Embodiment

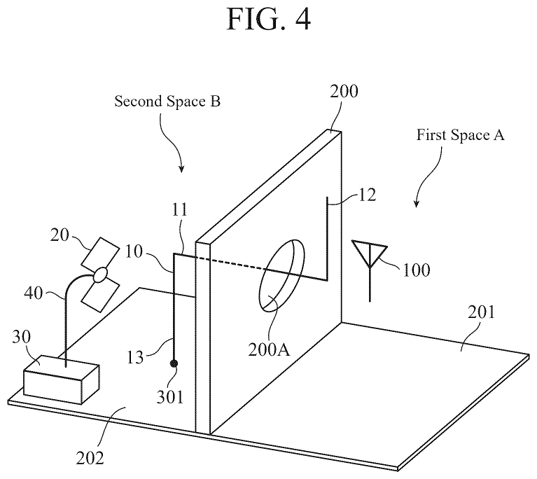

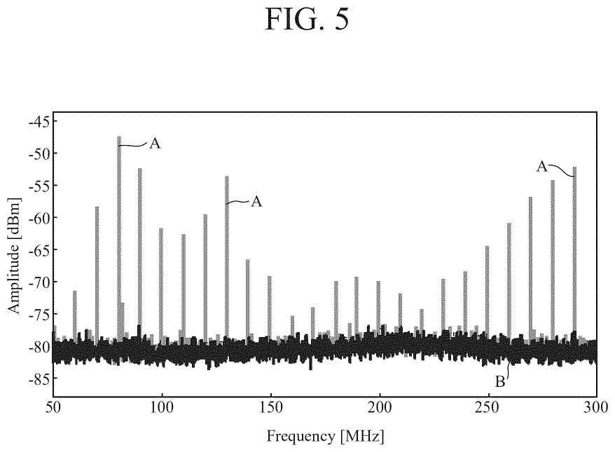

An electromagnetic wave detection device according to a fourth embodiment will be described with reference to FIGS. 4 and 5.

The electromagnetic wave detection device according to the fourth embodiment is different from the electromagnetic wave detection device according to the first embodiment in that, in the electromagnetic wave detection device according to the first embodiment, the detection unit 20 is a biconical antenna which is an example of a receiving antenna, and the measurement unit 30 is a spectrum analyzer, and in terms of the ground point at which a contact point provided at one end portion of the extending portion 13 of the metal wire 10 is connected as in the electromagnetic wave detection device according to the second embodiment, and is the same in other points.

In FIG. 4, the same reference numerals as those in FIGS. 1 to 3 denote the same or corresponding parts.

In addition, a description will be given assuming that the electromagnetic wave observation unit 10 is a metal wire 10, a biconical antenna 20 is used for the detection unit 20, and the measurement unit 30 is a spectrum analyzer 30.

The biconical antenna 20 is laid in proximity to the extending portion 13 of the metal wire 10, and an electromagnetic wave detection signal from the output of the biconical antenna 20 is input to the spectrum analyzer 30 via the coaxial cable 40.

Next, in the electromagnetic wave detection device according to the fourth embodiment, the received signal strength to the electromagnetic wave from the electromagnetic wave generation source 100 was verified.

The first space A and the second space B are both a shield room, and a through hole 200A having a diameter of 0.25 m or less corresponding to a wavelength of ¼ when the maximum frequency of the electromagnetic wave is 300 MHz is formed in a partition plate 200 that partitions the first space A and the second space B.

As the electromagnetic wave generation source 100 used for verification, a 1 W comb generator that generates electromagnetic waves at intervals of 10 MHz was used. The comb generator outputs a substantially constant output voltage in a range of 50 MHz to 300 MHz.

One end of a 20 cm cable was attached to the output terminal of the comb generator (the core wire of the coaxial terminal), and the other end of the cable on the side not connected to the comb generator was an open end.

The metal wire 10 was set to 1 m, and the receiving unit in the protruding portion 12 of the metal wire 10 was arranged side by side with a cable connected to the output terminal of the comb generator at an interval of 20 cm.

The extending portion 13 of the metal wire 10 was extended vertically by 30 cm, a crimp terminal was attached to the tip, and connected to the ground point 301 on the floor of the shield room forming the second space B with a bolt.

The biconical antenna 20 was disposed at a distance of 50 cm in the horizontal direction from the extending portion 13 of the metal wire 10.

An output end of the biconical antenna 20 and an input end of the spectrum analyzer 30 are connected by a 3 m coaxial cable 40.

With such a configuration, FIG. 5 illustrates a result of measuring the received signal strength with respect to the frequency of the electromagnetic wave emitted from the comb generator 100 by the spectrum analyzer 30.

In FIG. 5, the horizontal axis represents the frequency of the electromagnetic wave emitted from the comb generator 100, and the vertical axis represents the received signal strength.

In FIG. 5, a bar line A indicated by gray at intervals of 10 MHz indicates the received signal strength in the electromagnetic wave detection device according to the fourth embodiment.

In FIG. 5, a wavy line B indicated by dark gray indicates a measurement result obtained by measuring a comparative example in which the metal wire 10 is removed for comparison.

The comparative example was verified under the same conditions as those of the electromagnetic wave detection device according to the fourth embodiment except that the metal wire 10 was removed.

In the measurement result of the comparative example, although the frequency is 90 MHz and a part of the signal of the comb generator is received and the amplitude is −74 dBm, the amplitude is in the range of +3 dBm of −80 dBm in which the receiver sensitivity is the measurement limit in substantially the entire range of 50 MHz to 300 MHz.

This measurement result is considered to be a result of detecting leakage as an evanescent wave from the first space A to the second space B via the through hole 200A.

On the other hand, in the measurement result of the electromagnetic wave detection device according to the fourth embodiment, the amplitude is-70 dBm or more in substantially the entire range of 50 MHz to 300 MHz.

As is apparent from the verification result, the electromagnetic wave detection device according to the fourth embodiment has a receiver sensitivity improved by 10 dBm or more in substantially the entire range of 50 MHz to 300 MHz, and in particular, has an effect that a large voltage of −50 dBm or more can be received in the 80 MHz band.

### Fifth Embodiment

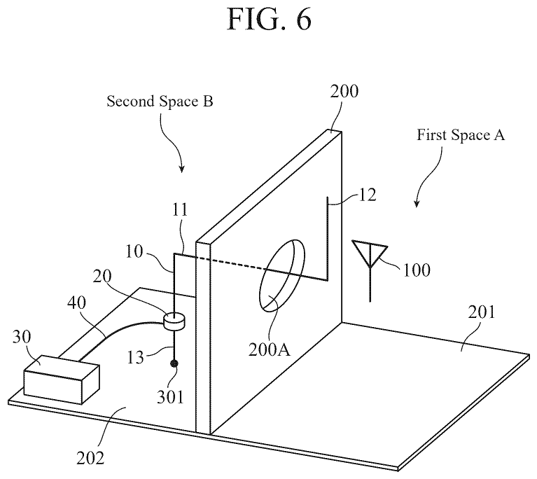

An electromagnetic wave detection device according to a fifth embodiment will be described with reference to FIG. 6.

The electromagnetic wave detection device according to the fifth embodiment is different from the electromagnetic wave detection device according to the first embodiment in that, in the electromagnetic wave detection device according to the first embodiment, the detection unit 20 is a current probe which is an example of a current sensor, and the measurement unit 30 is a spectrum analyzer, and in terms of the ground point at which a contact point provided at one end portion of the extending portion 13 of the metal wire 10 is connected as in the electromagnetic wave detection device according to the second embodiment, and is the same in other points.

In FIG. 6, the same reference numerals as those in FIGS. 1 to 4 denote the same or corresponding parts.

In the following description, a description will be given assuming that the electromagnetic wave observation unit 10 is a metal wire 10, the detection unit 20 is a current probe, and the measurement unit 30 is a spectrum analyzer 30.

The current probe 20 is attached to the extending portion 13 of the metal wire 10, detects a current flowing through the extending portion 13, and an electromagnetic wave detection signal based on the current, which is an output of the current probe 20, is input to the spectrum analyzer 30 via the coaxial cable 40.

In the electromagnetic wave detection device according to the fifth embodiment, when the receiver sensitivity to the electromagnetic wave from the electromagnetic wave generation source 100 was verified as in the electromagnetic wave detection device according to the fourth embodiment, measurement results were similar to the measurement results of the bar line A indicated by the gray color at intervals of 10 MHz illustrated in FIG. 5 were obtained.

Also in the electromagnetic wave detection device according to the fifth embodiment, the receiver sensitivity is improved by 10 dBm or more in substantially the entire range of 50 MHz to 300 MHz, and in particular, in the 80 MHz band, a large voltage of −50 dBm or more can be received.

### Sixth Embodiment

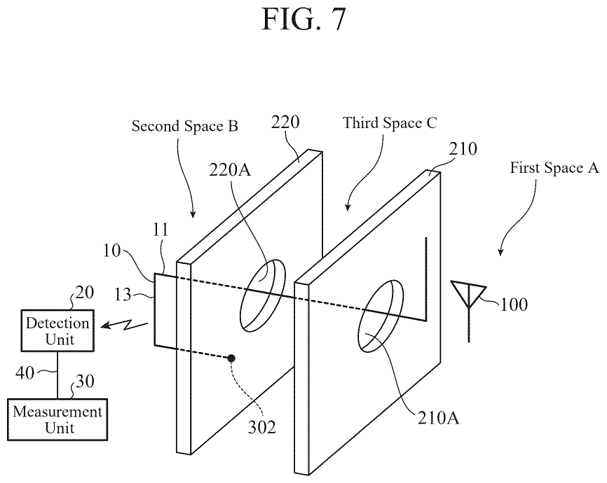

An electromagnetic wave detection device according to a sixth embodiment will be described with reference to FIG. 7.

The electromagnetic wave detection device according to the sixth embodiment is different from the electromagnetic wave detection device according to the first embodiment in that, in the electromagnetic wave detection device according to the first embodiment, the electromagnetic wave detection device is constituted by two conductors 210 and 220 arranged to face each other with a third space C interposed therebetween, and is the same in other points.

In FIG. 7, the same reference numerals as those in FIGS. 1 to 6 denote the same or corresponding parts.

In the following description, the electromagnetic wave observation unit 10 will be described as a metal wire 10.

The conductor 210 partitions the first space A where the electromagnetic wave generation source 100 is disposed and the third space C, and has a through hole 210A through which the penetrating portion 11 of the metal wire 10 passes.

The conductor 220 partitions the second space B where the electromagnetic wave detection device is disposed and the third space C, and has a through hole 220A through which the penetrating portion 11 of the metal wire 10 passes.

The conductor 220 has a ground point 300 to which a contact point provided at one end portion of the extending portion 13 of the metal wire 10 is connected.

The conductor 210 and the conductor 220 are arranged to face each other, and the through hole 210A and the through hole 220A are also formed at positions facing each other.

Note that the conductor 210 and the conductor 220 are not necessarily arranged to face each other, and the through hole 210A and the through hole 220A are not necessarily formed at positions facing each other.

The electromagnetic wave detection device according to the sixth embodiment configured as described above also has the same effect as the electromagnetic wave detection device according to the first embodiment.

### Seventh Embodiment

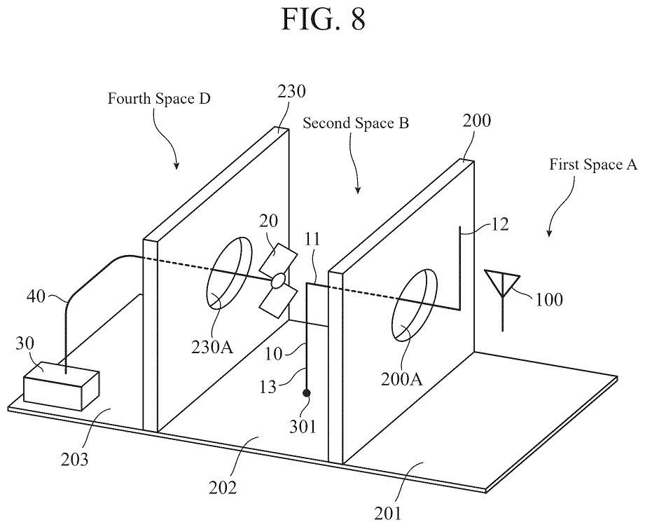

An electromagnetic wave detection device according to a seventh embodiment will be described with reference to FIG. 8.

The electromagnetic wave detection device according to the seventh embodiment is different from the electromagnetic wave detection device according to the first embodiment in that the measurement unit 30 is partitioned from the second space B by a second partition plate 230 that attenuates the propagation of the electromagnetic wave, and is disposed in a fourth space D different from the first space A and the second space B, and in terms of the ground point 301 at which the contact point provided at one end portion of the extending portion 13 of the metal wire 10 is connected as in the electromagnetic wave detection device according to the second embodiment, and is the same in other points.

In FIG. 8, the same reference numerals as those in FIGS. 1 to 7 denote the same or corresponding parts.

In addition, the electromagnetic wave observation unit 10 will be described as a metal wire 10.

The second partition plate 230 has a through hole 230A through which a coaxial cable 40 connecting the output end of the antenna of the detection unit 20 and the input end of the spectrum analyzer as the measurement unit 30 passes.

The measurement unit 30 is partitioned by the second partition plate 230 and disposed in the fourth space D which is another space different from the first space A and the second space B, and the electromagnetic wave detection signal from the detection unit 20 is input thereto via the coaxial cable 40.

The electromagnetic wave detection device according to the seventh embodiment configured as described above also has the same effect as the electromagnetic wave detection device according to the first embodiment.

Furthermore, by partitioning the second space B in which the extending portion 13 of the metal wire 10 and the antenna 20 that receives the electromagnetic wave emitted from the extending portion 13 are arranged and the fourth space D in which the spectrum analyzer 30 is disposed, the electromagnetic wave emitted by the spectrum analyzer 30 and the disturbance noise superimposed on the power supply line and the signal line necessary for driving the spectrum analyzer 30 do not affect the extending portion 13 of the metal wire 10 and the antenna 20 arranged in the second space B.

Note that what is used for the detection unit 20 is not limited to the antenna, and may be the electromagnetic field sensor or the current sensor exemplified in the first embodiment.

The measurement unit 30 is not limited to the spectrum analyzer, and may be the oscilloscope or the real-time spectrum analyzer exemplified in the first embodiment.

### Eighth Embodiment

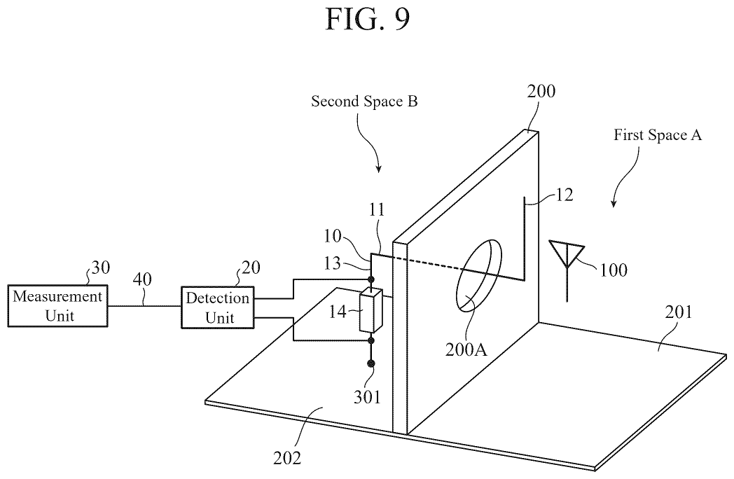

An electromagnetic wave detection device according to an eighth embodiment will be described with reference to FIG. 9.

The electromagnetic wave detection device according to the eighth embodiment is different from the electromagnetic wave detection device according to the first embodiment in that the electromagnetic wave detection device according to the eighth embodiment includes a passive element circuit 14 in which the electromagnetic wave observation unit 10 is connected between one end of the extending portion 13 of the metal wire and the ground point, and in terms of the ground point 301 at which one end portion of the electromagnetic wave observation unit 10, that is, the other terminal of the passive element circuit 14 is connected, and is the same in other points.

In FIG. 9, the same reference numerals as those in FIGS. 1 to 8 denote the same or corresponding parts.

The electromagnetic wave observation unit 10 includes a metal wire and a passive element circuit 14.

The passive element circuit 14 has two terminals, one terminal is connected to one end of the extending portion 13 of the metal wire, and the other terminal is connected to the ground point 301. The other terminal of the passive element circuit 14 and the ground point 301 may be connected directly or via a metal wire.

In the passive element circuit 14, one terminal connected to one end of the extending portion 13 of the metal wire in the electromagnetic wave observation unit 10 and the other terminal connected to the ground point are electrically conductive for the direct current.

The passive element circuit 14 may be a single passive element of a coil such as a resistor having a resistance value of 1 kΩ or less or a normal mode choke coil.

In addition, the passive element circuit 14 may be a circuit obtained by combining passive elements based on passive elements such as resistors or coils.

For example, the passive element circuit 14 may be a circuit in which a diode is connected in parallel with a passive element of a resistor or a coil.

In this case, when the receiver sensitivity of the protruding portion 12 of the metal wire in the electromagnetic wave observation unit 10 is high, a large voltage is prevented from being applied to the measurement unit 30 by the diode, and the measurement unit 30 is prevented from being instantly broken.

When the frequency characteristic and the amplitude of the electromagnetic wave at the time of abnormality from the electromagnetic wave generation source 100 are known, the passive element circuit 14 resonates with the frequency of the electromagnetic wave at the time of abnormality from the electromagnetic wave generation source 100.

In this case, the passive element circuit 14 is a resonance circuit in which a normal mode choke coil and a capacitor are connected in parallel.

The resonance frequency of the resonance circuit constituting the passive element circuit 14 in this case is selected by a) the separation distance and the parallel running distance between the protruding portion 12 of the metal wire and the electromagnetic wave generation source 100 in the electromagnetic wave observation unit 10, b) the entire length of the metal wire in the electromagnetic wave observation unit 10, c) the capacitance due to the parasitic component generated between the metal wire and the conductor plate 200 in the electromagnetic wave observation unit 10, and d) the circuit topology and the circuit constant of the resonance circuit constituting the passive element circuit 14.

By making the passive element circuit 14 a resonance circuit having a resonance frequency that meets the conditions in this manner, the impedance between both terminals of the passive element circuit 14 can be very large, and the voltage between both terminals of the passive element circuit 14 increases.

In addition, since the impedance of the coil is low with respect to a direct current or a low-frequency signal such as 50 Hz or 60 Hz, which is a commercial frequency close to the direct current, the low-frequency signal detected by the protruding portion 12 flows to the ground point 301, and thus the metal wire is not charged even when the metal wire is disposed in an environment of a strong electric field or a strong magnetic field.

As a result, a high-impedance probe can be used as the detection unit 20, the high-impedance probe can obtain a large voltage between both terminals of the passive element circuit 14 as a receiving voltage, and a high-sensitivity electromagnetic wave detection signal can be output from the high-impedance probe.

Furthermore, with respect to frequencies other than the resonance frequency of the resonance circuit constituting the passive element circuit 14, the impedance between both terminals of the passive element circuit 14 is low, a voltage due to a frequency other than the resonance frequency hardly appears between both terminals of the passive element circuit 14, and false detection can be prevented.

When the frequency of the electromagnetic wave at the time of abnormality from the electromagnetic wave generation source 100 is 10 MHz or less, the passive element circuit 14 is a series circuit of resistance of about 1 kQ and a normal mode choke coil.

Since the resistor enters in series and hinders the flow of electrons, it is more likely to be charged than when there is no resistor, and thus it cannot be used in a strong electric field or a strong magnetic field, but since electric charges flow through the resistor little by little, it can be used in a region where the electric field and the magnetic field are relatively weak.

In addition, since a high-impedance can be obtained at a low-frequency (for example, 100 kHz or less) due to the presence of resistor, it is effective when the frequency generated at the time of abnormality is low.

Also in this case, a high-impedance probe can be used as the detection unit 20, and even if the frequency of the electromagnetic wave at the time of abnormality from the electromagnetic wave generation source 100 is low, a highly sensitive electromagnetic wave detection signal can be output from the high-impedance probe.

The detection unit 20 may be an electromagnetic field sensor or a current sensor which is the non-contact sensor exemplified in the first embodiment.

In the eighth embodiment, since the electromagnetic wave observation unit 10 includes the passive element circuit 14, the detection unit 20 measures the voltage between both terminals of the passive element circuit 14, so that the electromagnetic wave detected and observed by the electromagnetic wave observation unit 10 can be detected and output to the measurement unit 30 as the electromagnetic wave detection signal.

In this case, the detection unit 20 uses a contact sensor using an active probe such as a field effect transistor (FET) probe or a probe having a high input impedance such as a high-impedance specification passive probe.

By using a contact sensor by a probe as the detection unit 20, the voltage between both terminals of the passive element circuit 14 can be measured with high accuracy.

Note that an optical insulation probe can also be used as the detection unit 20.

In addition, a coaxial cable can be used as the detection unit 20.

In the coaxial cable as the detection unit 20, a core wire of the coaxial cable is connected between one terminal of the passive element circuit 14 and an input end of the measurement unit 30, and an outer conductor of the coaxial cable is connected to the other terminal of the passive element circuit 14 or a conductor to be grounded.

Note that the core wire of the coaxial cable may be connected between the other terminal of the passive element circuit 14 and the input end of the measurement unit 30, and the outer conductor of the coaxial cable may be connected to one terminal of the passive element circuit 14.

The voltage between both terminals of the passive element circuit 14 can be measured by the coaxial cable as the detection unit 20, and can be output to the measurement unit 30 as an electromagnetic wave detection signal.

When the impedance between both terminals of the passive element circuit 14, for example, the impedance at 10 MHz is sufficiently lower than 1 kΩ in the internal impedance of the measurement unit 30, for example, 50Ω, the combined impedance is approximately 50Ω, so that an operational amplifier having a large input impedance is connected to the preceding stage of the measurement unit 30.

When the oscilloscope is used as the measurement unit 30, the input impedance of the oscilloscope is set to 1 MΩ.

The electromagnetic wave detection device according to the eighth embodiment configured as described above also has the same effect as the electromagnetic wave detection device according to the first embodiment.

In addition, since the electromagnetic wave observation unit 10 includes the passive element circuit 14 connected between one end of the extending portion 13 of the metal wire and the ground point, the metal wire constituting the electromagnetic wave observation unit 10 is connected to the ground point 301 with low impedance to prevent charging to the metal wire, so that the charge amount in the metal wire is small. As a result, the metal wire is less likely to receive the Lorentz force due to changes in the electric field and the magnetic field, and metal fatigue of the metal wire and the passive element circuit 14 is less likely to occur, so the metal wire is less likely to come off from the attachment location over a long period.

Furthermore, since the passive element circuit 14 is a resonance circuit in which the normal mode choke coil and the capacitor are connected in parallel, the detection sensitivity is high with respect to the resonance frequency of the resonance circuit, and the electromagnetic wave detection signal can be obtained at a high S/N ratio.

Furthermore, since the detection unit 20 can measure the voltage between both terminals of the passive element circuit 14 with high accuracy by using, as the detection unit 20, a contact sensor as a probe, an electromagnetic wave detection signal with high receiver sensitivity can be obtained.

Note that, although the electromagnetic wave detection device according to the eighth embodiment uses the passive element circuit 14, it is sufficient that the electromagnetic wave detection device has two terminals of one terminal connected to one end of the extending portion 13 of the metal wire in the electromagnetic wave observation unit 10 and the other terminal connected to the ground point, and one terminal and the other terminal are conductive for the direct current, that is, have low impedance between both ends. Therefore, instead of the passive element circuit 14, a circuit using a semiconductor element that is an active element having low impedance during use may be used.

In short, the circuit element is a passive element of a resistor, er a coil, or an active element of a semiconductor element, or a circuit obtained by combining these circuit elements, and the impedance between the two terminals, that is, the one end of the extending portion 13 of the metal wire and the ground point 301 may be higher than the impedance of the metal wire at least in the frequency band of the electromagnetic wave from the electromagnetic wave generation source 100.

### Ninth Embodiment

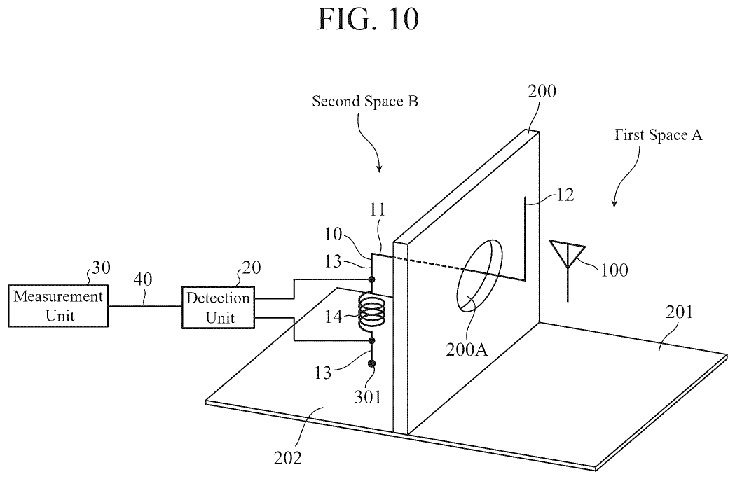

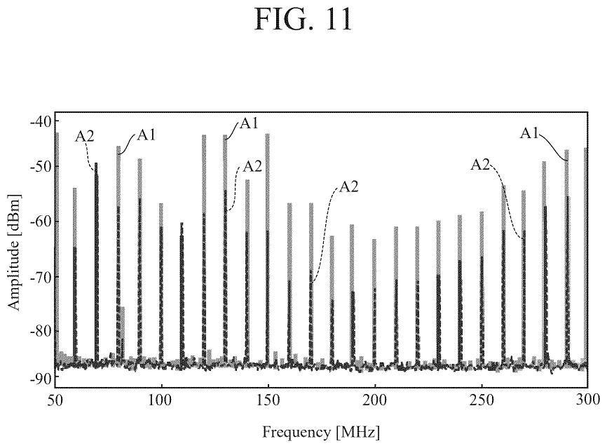

An electromagnetic wave detection device according to a ninth embodiment will be described with reference to FIGS. 10 and 11.

The electromagnetic wave detection device according to the ninth embodiment uses, in the electromagnetic wave detection device according to the eighth embodiment, a normal mode choke coil alone or a resistor which is an example of a passive element for the passive element circuit 14, a high-impedance probe which is a passive probe for the detection unit 20, and a spectrum analyzer for the measurement unit 30.

In FIG. 10, the same reference numerals as those in FIGS. 1 to 9 denote the same or corresponding parts.

In the following description, the electromagnetic wave observation unit 10 will be described as a metal wire 10, the detection unit 20 as a high-impedance probe 20, and the measurement unit 30 as a spectrum analyzer 30.

One terminal of the normal mode choke coil which is the passive element circuit 14 or the resistor is connected to one end of the extending portion 13 of the metal wire, and the other terminal of the normal mode choke coil or the resistor is connected to the ground point 301.

The high-impedance probe 20 is brought into contact with both terminals of the normal mode choke coil or the resistor.

The high-impedance probe 20 outputs a voltage appearing between both terminals of the normal mode choke coil or the resistor as an electromagnetic wave detection signal to the input end of the spectrum analyzer 30 via the coaxial cable 40.

In the electromagnetic wave detection device according to the ninth embodiment, the receiver sensitivity to the electromagnetic wave from the electromagnetic wave generation source 100 was verified.

The first space A and the second space B are both a shield room, and a through hole 200A having a diameter of 0.25 m or less corresponding to a wavelength of ¼ when the maximum frequency of the electromagnetic wave is 300 MHz is formed in a partition plate 200 that partitions the first space A and the second space B.

As the electromagnetic wave generation source 100 used for verification, a 1 W comb generator that generates electromagnetic waves at intervals of 10 MHz was used. The comb generator outputs a substantially constant output voltage in a range of 50 MHz to 300 MHz.

One end of a 20 cm cable was attached to the output terminal of the comb generator (the core wire of the coaxial terminal), and the other end of the cable on the side not connected to the comb generator was an open end.

As the high-impedance probe 20, a high-impedance probe capable of measuring 50 MHz to 300 MHz was used.

The metal wire 10 was set to 1 m, and the receiving unit in the protruding portion 12 of the metal wire 10 was provided with a cable connected to the output terminal of the comb generator and a length of 10 cm at an interval of 30 cm.

The extending portion 13 of the metal wire 10 was extended vertically by 25 cm, and one end of the extending portion 13 was connected to one terminal of the normal mode choke coil or the resistor.

The other terminal of the normal mode choke coil or the resistor was connected to the other end of the metal wire to which the crimp terminal was attached at one end, the crimp terminal attached to one end of the metal wire was connected to the ground point 301 on the floor of the shield room forming the second space B with a bolt, and the other terminal of the normal mode choke coil or the resistor was connected to the ground point 301 via the metal wire.

When the passive element circuit 14 was a normal mode choke coil, an SF-T12-30 manufactured by TDK having an impedance of 35 μH was used.

When the passive element circuit 14 was a resistor, a lead resistor having an impedance of 50Ω was used.

With such a configuration, FIG. 11 illustrates a result of measuring the received signal strength with respect to the frequency of the electromagnetic wave emitted from the comb generator 100 by the spectrum analyzer 30.

In FIG. 11, the horizontal axis represents the frequency of the electromagnetic wave emitted from the comb generator 100, and the vertical axis represents the received signal strength.

In FIG. 11, a bar line A1 indicated by gray at intervals of 10 MHz indicates the received signal strength in the electromagnetic wave detection device according to the ninth embodiment in a case where a normal mode choke coil is used as the passive element circuit 14.

In FIG. 11, a bar line A2 indicated by dark gray indicates received signal strength in the electromagnetic wave detection device according to the ninth embodiment in a case where a resistor is used as the passive element circuit 14.

As shown in FIG. 11, in the measurement result of the electromagnetic wave detection device according to the ninth embodiment in the case of using the normal mode choke coil as the passive element circuit 14, the amplitude is-70 dBm or more in substantially the entire range of 50 MHz to 300 MHz.

In the measurement result of the electromagnetic wave detection device according to the ninth embodiment in the case of using a resistor as the passive element circuit 14, the amplitude is-65 dBm or more in substantially the entire range of 50 MHz to 300 MHz.

As is apparent from the verification result, the electromagnetic wave detection device according to the ninth embodiment in the case of using the normal mode choke coil has the receiver sensitivity improved by 10 dBm or more in substantially the entire range of 50 MHz to 300 MHz, and the electromagnetic wave detection device according to the ninth embodiment in the case of using the resistor has the receiver sensitivity improved by 5 dBm or more in substantially the entire range of 50 MHz to 300 MHz, and has an effect that a large voltage can be received.

In particular, it is preferable to use a normal-mode choke coil. In addition, when the normal mode choke coil is used, a signal of a specific frequency can be efficiently received.

When a resistor is used, the 5 dBm sensitivity can be increased by increasing the impedance from 50Ω to 500Ω.

### Tenth Embodiment

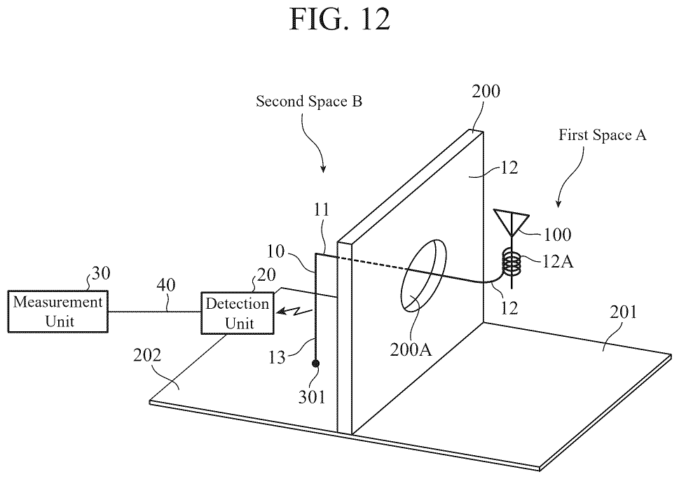

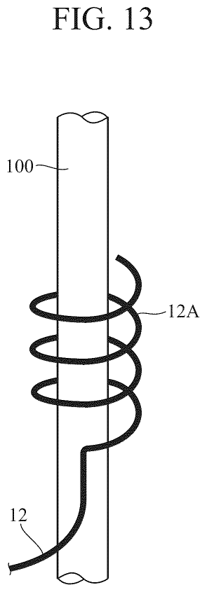

An electromagnetic wave detection device according to a tenth embodiment will be described with reference to FIGS. 12 and 13.

The electromagnetic wave detection device according to the tenth embodiment is an electromagnetic wave detection device that targets a cable as the electromagnetic wave generation source 100 and detects an abnormality due to an electromagnetic wave generated in the cable.

Since the electromagnetic wave detection device according to the tenth embodiment targets a cable as the electromagnetic wave generation source 100, in the electromagnetic wave detection device according to the first embodiment, the protruding portion 12 of the metal wire in the electromagnetic wave observation unit 10 has a specific structure, and the electromagnetic wave detection device according to the tenth embodiment is different from the electromagnetic wave detection device according to the first embodiment in terms of the ground point at which a contact point provided at one end portion of the extending portion 13 of the metal wire 10 is connected as in the electromagnetic wave detection device according to the second embodiment, and is the same in other points.

In FIG. 12, the same reference numerals as those in FIGS. 1 to 10 denote the same or corresponding parts.

As illustrated in FIG. 13, the protruding portion 12 of the metal wire in the electromagnetic wave observation unit 10 has a receiving unit 12A having a winding structure in which a tip portion is wound around a cable, which is the electromagnetic wave generation source 100, a plurality of times in a non-contact manner at the tip portion.

The number of windings by the winding structure is preferably 3 turns in consideration of the S/N ratio so as not to be easily detached from the cable 100. However, the winding is not limited to three turns, and the winding may be one turn or less such as a half turn as long as a necessary S/N ratio can be ensured.

In addition, the separation distance between the receiving unit 12A and the cable 100 does not depend on the winding diameter, but it is desirable to separate the separation distance 3 times or more the dielectric breakdown distance in consideration of safety from the distance in which the receiving unit 12A causes the dielectric breakdown, which is about 1 kV/mm.

In the case of measuring discharge such as partial discharge and spark discharge, a place where the partial discharge occurs is generally known in many cases.

Specifically, a portion having a switch mechanism such as a cable coating, an insulator holding the cable, a circuit breaker, and a power semiconductor device often generates a partial discharge due to aging deterioration.

The partial discharge thus generated propagates to a conductor such as a wiring, a cable, a bus bar, or a bus duct electrically connected to a place where the partial discharge is likely to occur.

The electromagnetic wave detection device according to the tenth embodiment uses a conductor such as a wiring, a cable, or a bus bar electrically connected to a place where partial discharge is likely to occur as the electromagnetic wave generation source 100, and provides the receiving unit 12A having a structure of winding around the conductor in the protruding portion 12 to detect the electromagnetic wave emitted from the conductor.

In the present disclosure, a wiring, a cable, a bus bar, and a bus duct are collectively referred to as a cable.

That is, the electromagnetic wave detection device according to the tenth embodiment can receive a signal derived from the electromagnetic wave generation source using the cable as the electromagnetic wave generation source 100.

In addition, since the receiving unit 12A having a structure of winding around the conductor with respect to a measurement target is provided, the receiver sensitivity to the electromagnetic wave emitted from the cable is high, and the S/N ratio of the disturbance noise with respect to the electromagnetic wave received from the conductor with respect to the measurement target is high, so that the measurement target can be specified even if there is another electromagnetic wave generation source different from the measurement target.

The electromagnetic wave detection device according to the tenth embodiment is not limited to abnormality detection when the partial discharge occurs, and may be used for abnormality detection in a high-speed signal, a switching signal, a control signal, or the like.

For example, a cable connected to a main circuit connected to a power semiconductor device that is a switching element in which a switching signal is generated is regarded as the electromagnetic wave generation source 100, and the receiving unit 12A having a winding structure is disposed on the cable connecting the power semiconductor device and the main circuit, whereby the electromagnetic wave emitted from the cable based on the abnormality in the power semiconductor device can be received with high sensitivity.

In addition, in a motor that is likely to cause the occurrence of the abnormality, the cable connecting the main circuit connected to the motor is regarded as the electromagnetic wave generation source 100, and the receiving unit 12A having the winding structure is disposed on the cable connecting the motor and the main circuit, so that the electromagnetic wave emitted from the cable based on the abnormality in the motor can be received with high sensitivity.

Furthermore, the receiving unit 12A having a winding structure wound around the electromagnetic wave generation source 100 in a non-contact manner is provided at the tip portion of the protruding portion 12 of the metal wire, but may be provided at the center portion of the protruding portion 12.

The electromagnetic wave detection device according to the tenth embodiment configured as described above also has the same effect as the electromagnetic wave detection device according to the first embodiment.

Moreover, by arranging the receiving unit 12A having a structure wound around the cable as the electromagnetic wave generation source 100 in a non-contact manner, the electromagnetic wave emitted from the cable can be received with high sensitivity, and a high S/N ratio can be obtained.

In the electromagnetic wave detection device according to the tenth embodiment, the electromagnetic wave observation unit 10 may include a passive element circuit 14 connected between one end of the extending portion 13 of the metal wire and the ground point 301 as in the electromagnetic wave detection device according to the eighth embodiment.

Since the electromagnetic wave observation unit 10 includes the passive element circuit 14, the received signal strength of the electromagnetic wave emitted from the electromagnetic wave generation source 100 can be increased, and the S/N ratio can be improved.

### Eleventh Embodiment

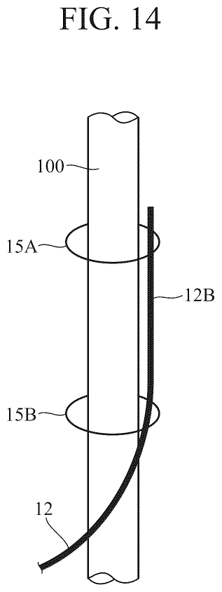

An electromagnetic wave detection device according to an eleventh embodiment will be described with reference to FIG. 14.

The electromagnetic wave detection device according to the tenth embodiment includes the receiving unit 12A having a winding structure in the protruding portion 12 of the metal wire in the electromagnetic wave observation unit 10, but the electromagnetic wave detection device according to the eleventh embodiment is different from the electromagnetic wave detection device according to the tenth embodiment in that the electromagnetic wave detection device according to the eleventh embodiment includes a receiving unit 12B that runs in parallel with the cable in a non-contact manner in the protruding portion 12, and is the same in other points.

In FIG. 14, the same reference numerals as those in FIGS. 12 and 13 denote the same or corresponding parts.

The protruding portion 12 of the metal wire in the electromagnetic wave observation unit 10 has a receiving unit 12B that runs in parallel with the cable, which is the electromagnetic wave generation source 100, in a non-contact manner at the tip portion.

The receiving unit 12B runs in parallel with the cable 100 via a dielectric, and a separation distance between the receiving unit 12B and the cable 100 is a distance equal to or longer than a dielectric breakdown distance.

A starting end and a terminating end of the receiving unit 12B that run in parallel are fixed to the cable by fixtures 15A and 15B such as a binding band (tie wrap), respectively.

The material of the fixtures 15A and 15B is preferably a dielectric in order to prevent short circuit and avoid interference with the protruding portion 12.

The electromagnetic wave detection device according to the eleventh embodiment configured as described above also has the same effect as the electromagnetic wave detection device according to the tenth embodiment.

The metal wire of the receiving unit 12B may be embedded in the mold case.

In this case, by having a structure in which one sides are opened and separated on the opposite side of the metal wire of the receiving unit 12B, attachment to the cable 100 becomes easy.

Moreover, since the structure of the receiving unit 12B can be made uniform, the electromagnetic wave can be received from the cable 100 with high reproducibility.

Note that the receiving unit 12B that runs in parallel with the cable, which is the electromagnetic wave generation source 100, in a non-contact manner is provided at the tip portion of the protruding portion 12 of the metal wire, but may be provided at the center portion of the protruding portion 12.

Furthermore, the electromagnetic wave generation source 100 is not limited to the cable, and may be, for example, the electromagnetic wave generation source 100 that is a semiconductor device, a rotating machine such as a motor, an electric motor, an insulator degraded material, or the like described in the first embodiment.

Even in these electromagnetic wave generation sources 100, the protruding portion 12 of the metal wire has a receiving unit 12B that runs in parallel with the electromagnetic wave generation source 100 in a non-contact manner, and the receiving unit 12B receives the electromagnetic wave from the electromagnetic wave generation source 100.

### Twelfth Embodiment

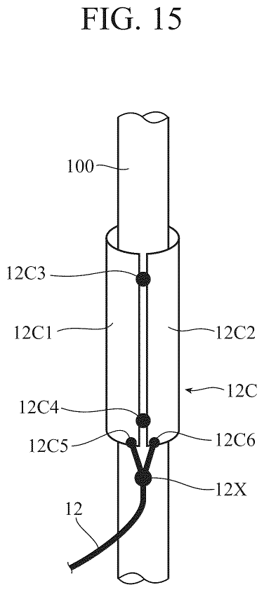

An electromagnetic wave detection device according to a twelfth embodiment will be described with reference to FIG. 15.

The electromagnetic wave detection device according to the tenth embodiment includes a receiving unit 12A having a winding structure in the protruding portion 12 of the metal wire in the electromagnetic wave observation unit 10, but the electromagnetic wave detection device according to the twelfth embodiment is different from the electromagnetic wave detection device according to the tenth embodiment in that the electromagnetic wave detection device according to the twelfth embodiment includes a receiving unit 12C formed of a receiving conductor plate surrounding the periphery of the cable in the protruding portion 12, and is the same in other points.

In FIG. 15, the same reference numerals as those in FIGS. 12 and 13 denote the same or corresponding parts.

The protruding portion 12 of the metal wire in the electromagnetic wave observation unit 10 has a receiving unit 12C made of a receiving conductor plate that surrounds the periphery of the cable in a non-contact manner on the cable that is the electromagnetic wave generation source 100 at the tip portion.

The receiving conductor plate constituting the receiving unit 12C includes a pair of metal bodies 12C1 and 12C2 each having a semicircular cross section, and hinges 12C3 and 12C4 that fit the pair of metal bodies 12C1 and 12C2 on both sides.

The pair of metal bodies 12C1 and 12C2 is electrically connected to the metal wire branched into two from a branch point 12X in the protruding portion 12 at connection points 12C5 and 12C6 at one end portion.

One sides of the pair of metal bodies 12C1 and 12C2 may be fitted with a hinge, the other sides may be electrically and mechanically connected, and the metal wire in the protruding portion 12 may be electrically connected to one metal body 12C1 without being branched.

The electromagnetic wave detection device according to the twelfth embodiment configured as described above also has the same effect as the electromagnetic wave detection device according to the tenth embodiment.

In addition, since at least one sides are opened and separated, attachment to the cable 100 is easy. It can also be attached to the cable 100 by retrofitting.

### Thirteenth Embodiment

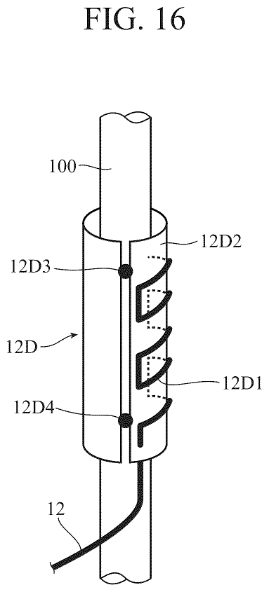

An electromagnetic wave detection device according to a thirteenth embodiment will be described with reference to FIG. 16.

The electromagnetic wave detection device according to the tenth embodiment includes the receiving unit 12A having a winding structure in the protruding portion 12 of the metal wire in the electromagnetic wave observation unit 10, but the electromagnetic wave detection device according to the thirteenth embodiment is different from the electromagnetic wave detection device according to the tenth embodiment in that the electromagnetic wave detection device according to the thirteenth embodiment includes a receiving unit 12D formed of a dielectric mold case with a built-in metal wire surrounding the periphery of the cable in the protruding portion 12, and is the same in other points.

In FIG. 16, the same reference numerals as those in FIGS. 12 and 13 denote the same or corresponding parts.

The protruding portion 12 of the metal wire in the electromagnetic wave observation unit 10 has a receiving unit 12D formed of a dielectric mold case with a built-in metal wire that surrounds the periphery of the cable in a non-contact manner with the cable that is the electromagnetic wave generation source 100 at the tip portion.

The dielectric mold case constituting the receiving unit 12D includes a tubular dielectric mold 12D2 having one sides separated from each other, a receiving metal wire 12D1 embedded in the dielectric mold 12D2 by routing a tip portion of the protruding portion 12 with a meander wire around one side of the dielectric mold 12D2, and hinges 12D3 and 12D4 fitting the separated one sides of the dielectric mold 12D2.

Although the receiving metal wire 12D1 is a continuous metal wire of the protruding portion 12, the receiving metal wire 12D1 may be another metal wire and electrically connected to the metal wire of the protruding portion 12.

In short, the receiving metal wire 12D1 may be integrated at the tip portion of the protruding portion 12 or may be separate.

The electromagnetic wave detection device according to the thirteenth embodiment configured as described above also has the same effect as the electromagnetic wave detection device according to the tenth embodiment.

Since one side of the tubular dielectric mold 12D2 is separated, it is easy to attach the dielectric mold to the cable 100. It can also be attached to the cable 100 by retrofitting.

Moreover, since the structure of the receiving unit 12D can be made uniform, the electromagnetic wave can be received from the cable 100 with high reproducibility.

### Fourteenth Embodiment

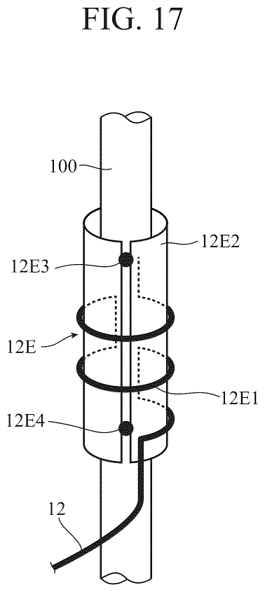

An electromagnetic wave detection device according to a fourteenth embodiment will be described with reference to FIG. 17.

The electromagnetic wave detection device according to the tenth embodiment includes the receiving unit 12A having a winding structure in the protruding portion 12 of the metal wire in the electromagnetic wave observation unit 10, but the electromagnetic wave detection device according to the fourteenth embodiment is different from the electromagnetic wave detection device according to the tenth embodiment in that the electromagnetic wave detection device according to the fourteenth embodiment includes a receiving unit 12E formed of a dielectric mold case with a built-in metal wire surrounding the periphery of the cable in the protruding portion 12, and is the same in other points.

In FIG. 17, the same reference numerals as those in FIGS. 12 and 13 denote the same or corresponding parts.

The protruding portion 12 of the metal wire in the electromagnetic wave observation unit 10 has a receiving unit 12E formed of a dielectric mold case with a built-in metal wire surrounding the periphery of the cable in a non-contact manner with the cable which is the electromagnetic wave generation source 100 at the tip portion.

The dielectric mold case constituting the receiving unit 12E includes a pair of dielectric molds 12E2 each having a semicircular cross section, a receiving metal wire 12E1 that is embedded inside the pair of dielectric molds 12E2 by routing a tip portion of the protruding portion 12 around the dielectric mold 12E2 with a meander wire bidirectionally passing between sides of the pair of dielectric molds 12E2 where each one side is separated from the other, and hinges 12E3 and 12E4 that are fitted on both sides of the pair of dielectric molds where each one side is separated from the other. Although the receiving metal wire 12E1 is a continuous metal wire of the protruding portion 12, the receiving metal wire 12E1 may be another metal wire and electrically connected to the metal wire of the protruding portion 12.

In short, the receiving metal wire 12E1 may be integrated at the tip portion of the protruding portion 12 or may be separate.

The electromagnetic wave detection device according to the fourteenth embodiment configured as described above also has the same effect as the electromagnetic wave detection device according to the tenth embodiment.

Since the receiving metal wire 12E1 is a meander wire that bidirectionally passes between the sides where one sides are separated, the parallel running area of the receiving metal wire 12E1 and the cable 100 can be increased, the electromagnetic wave emitted from the cable 100 can be received with high sensitivity, and a high S/N ratio can be obtained.

In addition, since the other sides of the pair of dielectric molds are opened and separated from each other, attachment to the cable 100 is easy. It can also be attached to the cable 100 by retrofitting.

### Fifteenth Embodiment

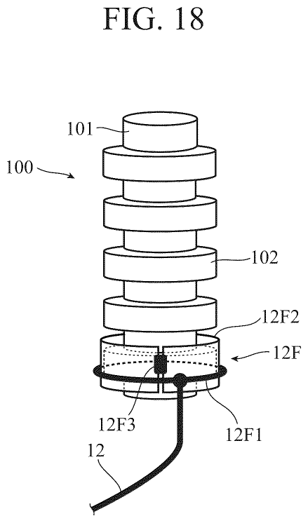

An electromagnetic wave detection device according to a fifteenth embodiment will be described with reference to FIG. 18.

The electromagnetic wave detection device according to the fifteenth embodiment is an electromagnetic wave detection device that targets an insulator inside a distribution board or a bushing of a transformer such as an oil type or a mold type as the electromagnetic wave generation source 100, and detects an abnormality by an electromagnetic wave generated in the insulator or the bushing.

When the coil inside the distribution board is discharged due to aging deterioration or the like, an electromagnetic wave based on the discharge of the coil is emitted from the insulator.

When the coil inside the transformer is discharged due to aging deterioration or the like, an electromagnetic wave based on the discharge of the coil is emitted from the bushing.

The electromagnetic wave detection device according to the fifteenth embodiment detects the electromagnetic wave emitted from the insulator or the bushing by a receiving unit 12F included in the protruding portion 12 of the metal wire in the electromagnetic wave observation unit 10, thereby indirectly detecting that the coil inside the distribution board or the coil inside the transformer is discharged due to aging deterioration or the like.

With reference to FIG. 18, the electromagnetic wave generation source 100 is an insulator, and the receiving unit 12F that receives the electromagnetic wave emitted from the insulator will be described.

The electromagnetic wave detection device is the same as the electromagnetic wave detection device according to the tenth embodiment except for the receiving unit 12F.

In FIG. 18, the same reference numerals as those in FIGS. 12 and 13 denote the same or corresponding parts.

The insulator 100 includes an insulator conductor 101 and an insulator body 102.

The protruding portion 12 of the metal wire in the electromagnetic wave observation unit 10 includes a receiving unit 12F formed of a dielectric mold case with a built-in metal wire and surrounding the periphery of the insulator body 102 on the insulator 100 which is the electromagnetic wave generation source 100 at the tip portion.

The dielectric mold case constituting the receiving unit 12F includes a tubular dielectric mold 12F2 whose one side is separated from the other, a receiving metal wire 12F1 in which the tip portion of the protruding portion 12 is embedded as a ring-shaped wiring inside the dielectric mold 12F2 around the dielectric mold 12F2, and a hinge 12F3 that fits the separated one side of the dielectric mold 12F2.

Although the receiving metal wire 12F1 is a continuous metal wire of the protruding portion 12, the receiving metal wire 12F1 may be another metal wire and electrically connected to the metal wire of the protruding portion 12.

In short, the receiving metal wire 12F1 may be integrated at the tip portion of the protruding portion 12 or may be separate.

The electromagnetic wave detection device according to the fifteenth embodiment configured as described above also has the same effect as the electromagnetic wave detection device according to the tenth embodiment.

Since one side of the tubular dielectric mold 12F2 is separated from the other, it is easy to attach the dielectric mold to the insulator 100. It can also be attached to the insulator 100 by retrofitting.

Moreover, since the structure of the receiving unit 12F can be made uniform, receiving the electromagnetic wave from the insulator 100 can be performed with high reproducibility.

In addition, since the receiving metal wire 12F1 is an open end of one end as the metal wire 10, a large current does not flow through the metal wire 10, that is, a current equal to or higher than the rated current does not flow through the metal wire 10, and the metal wire 10 is not melted.

### Sixteenth Embodiment

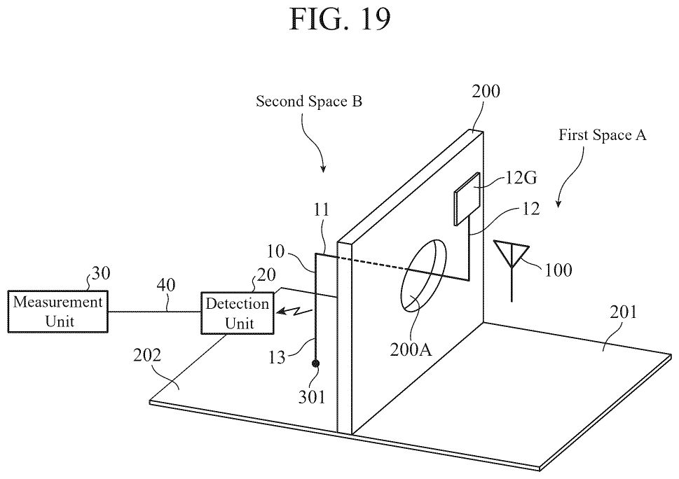

An electromagnetic wave detection device according to a sixteenth embodiment will be described with reference to FIG. 19.

The electromagnetic wave detection device according to the sixteenth embodiment includes, in the electromagnetic wave detection device according to the first embodiment, a receiving conductor plate 12G thicker than the metal wire constituting the protruding portion 12 at the tip portion of the protruding portion 12 of the metal wire in the electromagnetic wave observation unit 10, and the electromagnetic wave detection device according to the sixteenth embodiment is different from the electromagnetic wave detection device according to the first embodiment in terms of the ground point at which the contact point provided at one end portion of the extending portion 13 of the metal wire 10 is connected as in the electromagnetic wave detection device according to the second embodiment, and is the same in other points.

In FIG. 19, the same reference numerals as those in FIGS. 1 to 10 denote the same or corresponding parts.

The protruding portion 12 of the metal wire in the electromagnetic wave observation unit 10 includes a plate-like receiving conductor plate 12G having a width longer than the diameter of the metal wire constituting the protruding portion 12.

When the electromagnetic wave generation source 100 is a cable, the width of the receiving conductor plate 12G is preferably equal to or larger than the dimension of the cable.

The thickness of the receiving conductor plate 12G is a thickness that can maintain the structure.

The receiving conductor plate 12G is not necessarily provided at the tip of the protruding portion 12, and may be provided at the tip portion.

The receiving conductor plate 12G is not limited to a flat surface. For example, in a case where the electromagnetic wave generation source 100 is a cable, the receiving conductor plate may be an aspect having a curvature in accordance with the shape of the cable. The receiving conductor plate may have a structure thicker than the metal wire constituting the protruding portion 12, such as an elliptical shape other than a quadrangular shape, a bent shape, or a plate shape having a hole.

The receiving conductor plate 12G may have a plurality of plate-like portions thicker than the metal wire constituting the protruding portion 12 instead of one portion.

In particular, when a plurality of electromagnetic wave generation sources 100 to be a target of abnormality detection are adjacent to each other, the plate-shaped portion of the receiving conductor plate 12G is desirably arranged in the vicinity of each of the plurality of electromagnetic wave generation sources 100.

In addition, the larger the parasitic capacitance between the receiving conductor plate 12G and the electromagnetic wave generation source 100, the higher the receiver intensity of the electromagnetic wave from the electromagnetic wave generation source 100 in the receiving conductor plate 12G.

Therefore, the area of the receiving conductor plate 12G facing the electromagnetic wave generation source 100 is desirably about the same as or larger than the area of the electromagnetic wave generation source 100.

The area of the electromagnetic wave generation source 100 is, for example, the size of an insulator when the electromagnetic wave generation source 100 is the insulator. In this case, the area of the receiving conductor plate 12G is equal to or larger than that of the insulator, and the receiving conductor plate 12G is disposed to face the insulator.

In addition, in a case where the electromagnetic wave generation source 100 is a cable, the receiving conductor plate 12G having a vertically long area is disposed in parallel with the cable so as to face the cable.

In a case where the receiving conductor plate 12G has to be disposed of at a distance from the electromagnetic wave generation source 100, the facing area of the receiving conductor plate 12G is increased in order to increase the parasitic capacitance.

As described above, by increasing the facing area between the receiving conductor plate 12G and the electromagnetic wave generation source 100, the parasitic capacitance can be increased, the receiving conductor plate 12G can easily receive the electric field in the electromagnetic wave emitted from the electromagnetic wave generation source 100, and the receiver intensity in the receiving conductor plate 12G is increased.

When the electromagnetic wave generation source 100 is, for example, an insulator or a cable, a dielectric having a high relative permittivity may be interposed between the receiving conductor plate 12G and the electromagnetic wave generation source 100 to increase the parasitic capacitance between the receiving conductor plate 12G and the electromagnetic wave generation source 100.

Also in this case, the receiving conductor plate 12G easily receives the electric field in the electromagnetic wave from the electromagnetic wave generation source 100, and the receiver intensity in the receiving conductor plate 12G increases.

A region in the vicinity of the electromagnetic wave generation source 100, specifically, a region of one wavelength or less of the electromagnetic wave emitted from the electromagnetic wave generation source 100 is a Fresnel zone, and the ratio of the electric field component to the magnetic field component is not constant.

That is, there is a region in which the electric field component is dominant and a region in which the magnetic field component is dominant by the characteristics of the electromagnetic wave emitted from the electromagnetic wave generation source 100.

In the case of the region where the electric field component is dominant, the electric field component of the electromagnetic wave emitted from the electromagnetic wave generation source 100 can be efficiently received by disposing of the receiving conductor plate 12G to face the electromagnetic wave generation source 100.

In addition, in a case where the protruding portion 12 has to be disposed at a distance from the electromagnetic wave generation source 100, the receiver sensitivity of several dB is improved by providing the receiving conductor plate 12G as compared with a case where the protruding portion 12 is only a metal wire.

The electromagnetic wave detection device according to the sixteenth embodiment configured as described above also has the same effect as the electromagnetic wave detection device according to the first embodiment.

Furthermore, since the receiving conductor plate 12G thicker than the metal wire constituting the protruding portion 12 is provided at the tip portion of the protruding portion 12 of the metal wire in the electromagnetic wave observation unit 10, the receiver sensitivity to the electromagnetic wave emitted from the electromagnetic wave generation source 100 is improved.

In particular, in a region where the electric field component is dominant by the electromagnetic wave emitted from the electromagnetic wave generation source 100, the electric field component from the electromagnetic wave generation source 100 can be efficiently received, and the receiver sensitivity to the electromagnetic wave emitted from the electromagnetic wave generation source 100 is improved.

In the electromagnetic wave detection device according to the sixteenth embodiment, the electromagnetic wave observation unit 10 may include a passive element circuit 14 connected between one end of the extending portion 13 of the metal wire and the ground point 301 as in the electromagnetic wave detection device according to the eighth embodiment.

Since the electromagnetic wave observation unit 10 includes the passive element circuit 14, the received signal strength of the electromagnetic wave emitted from the electromagnetic wave generation source 100 can be increased, and the S/N ratio can be improved.

Further, the plate-shaped receiving conductor plate 12G having a width longer than the diameter of the metal wire constituting the protruding portion 12 is provided at the tip portion of the protruding portion 12 of the metal wire, but may be provided at the center portion of the protruding portion 12.

Furthermore, a plurality of plate-shaped receiving conductor plates 12G may be provided at the tip portion, the center portion, and the like of the protruding portion 12.

### Seventeenth Embodiment

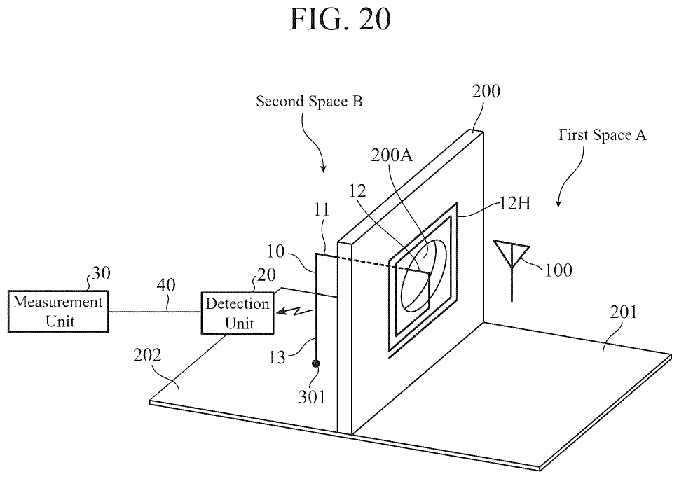

An electromagnetic wave detection device according to a seventeenth embodiment will be described with reference to FIG. 20.

The electromagnetic wave detection device according to the seventeenth embodiment is different from the electromagnetic wave detection device according to the nineteenth embodiment in that the electromagnetic wave detection device according to the nineteenth embodiment includes the receiving conductor plate 12G thicker than the metal wire constituting the protruding portion 12 at the tip portion of the protruding portion 12 of the metal wire in the electromagnetic wave observation unit 10, but the electromagnetic wave detection device according to the seventeenth embodiment includes a receiving unit 12H having a winding structure having a surface parallel to the plane of the partition plate 200, and is the same in other points.

In FIG. 20, the same reference numerals as those in FIGS. 1 to 10 and 19 denote the same or corresponding parts.

The protruding portion 12 of the metal wire in the electromagnetic wave observation unit 10 includes a receiving unit 12H having a spiral wire structure in which the metal wire is wound in a spiral shape spreading in a plane parallel to the plane of the partition plate 200.

The receiving unit 12H has a winding structure and a structure close to a helical antenna.

In addition, since the winding structure in the receiving unit 12H is a structure extending in a plane, the winding structure has directivity in the forward direction of the plane.

The central axis of the winding structure in the receiving unit 12H is not limited to the one that coincides with the central axis of the through hole 200A of the partition plate 200. In addition, the plane of the winding structure in the receiving unit 12H is not limited to the plane parallel to the plane of the partition plate 200, and may be a plane parallel to the plane of another conductor plate. Furthermore, the winding structure in the receiving unit 12H does not fit within a plane, and may have a thick structure.

The winding structure in the receiving unit 12H is not limited to the winding structure from the inside to the outside, and may be a winding structure from the outside to the inside.

In a case of a region where a magnetic field component is dominant by an electromagnetic wave emitted from the electromagnetic wave generation source 100, the receiving unit 12H having a winding structure is disposed to face the electromagnetic wave generation source 100, so that a magnetic field component in the electromagnetic wave emitted from the electromagnetic wave generation source 100 can be efficiently received.

When the electromagnetic wave emitted from the electromagnetic wave generation source 100 is close to a circularly polarized wave, the electromagnetic wave emitted from the electromagnetic wave generation source 100 can be received with high receiver sensitivity because the receiving unit 12H has a winding structure has a structure close to that of a helical antenna.

The electromagnetic wave detection device according to the seventeenth embodiment configured as described above also has the same effect as the electromagnetic wave detection device according to the first embodiment.

Furthermore, since the receiving unit 12H has a spiral structure provided at the tip portion of the protruding portion 12 of the metal wire in the electromagnetic wave observation unit 10, the receiver sensitivity to the electromagnetic wave emitted from the electromagnetic wave generation source 100 is improved.

In particular, the magnetic field component from the electromagnetic wave generation source 100 can be efficiently received in a region where the magnetic field component is dominant by the electromagnetic wave emitted from the electromagnetic wave generation source 100, and the receiver sensitivity to the electromagnetic wave emitted from the electromagnetic wave generation source 100 is improved.

In addition, when the electromagnetic wave emitted from the electromagnetic wave generation source 100 is close to a circularly polarized wave, it is possible to obtain the electromagnetic wave emitted from the electromagnetic wave generation source 100 with high receiver sensitivity.

Furthermore, since the receiving unit 12H having a spiral structure extending on a plane has directivity in the forward direction of the plane, even if the first space A in which the electromagnetic wave generation source 100 is disposed of does not have sufficient space, the receiving unit 12H can be disposed of in the first space A to receive the electromagnetic wave emitted from the electromagnetic wave generation source 100 with high receiver sensitivity.

Note that the receiving unit 12H and the receiving conductor plate 12G illustrated in the sixteenth embodiment connected to the tip of the receiving unit 12H may be provided at the tip portion of the protruding portion 12 of the metal wire in the electromagnetic wave observation unit 10.

In this case, the electromagnetic wave emitted from the electromagnetic wave generation source 100 can be received with high receiver sensitivity in both the region where the electric field component is dominant and the region where the magnetic field component is dominant in the electromagnetic wave emitted from the electromagnetic wave generation source 100.

In the electromagnetic wave detection device according to the seventeenth embodiment, similarly to the electromagnetic wave detection device according to the eighth embodiment, the electromagnetic wave observation unit 10 may include a passive element circuit 14 connected between one end of the extending portion 13 of the metal wire and the ground point 301.

Since the electromagnetic wave observation unit 10 includes the passive element circuit 14, the received signal strength of the electromagnetic wave emitted from the electromagnetic wave generation source 100 can be increased, and the S/N ratio can be improved.

### Eighteenth Embodiment

An electromagnetic wave detection device according to an eighteenth embodiment will be described.

In the electromagnetic wave detection device according to the eighteenth embodiment, with respect to each of the electromagnetic wave detection devices according to the first embodiment to the seventeenth embodiment, in the first space A, between the open end of the protruding portion 12 of the metal wire in the electromagnetic wave observation unit 10 and the ground point located in the first space A, an impedance unit having an impedance higher than an impedance between the extending portion 13 of the metal wire in the electromagnetic wave observation unit 10 and the ground point is connected.

In the electromagnetic wave detection devices according to the first to seventh embodiments and the 10 to 17 embodiments, the impedance between the extending portion 13 of the metal wire and the grounding point in the electromagnetic wave observation unit 10 is the impedance between the contact point provided at one end of the extending portion 13 and the grounding point (the grounding point 300 in the conductor plate 200 or the ground point 301 in the conductor plate 202) located in the second space B. In the electromagnetic wave detection devices according to the eighth and ninth embodiments, the impedance is the impedance of the passive element circuit 14 connected between one end of the extending portion 13 of the metal wire and the ground point 301.

The impedance unit is a diode, or an insulating fiber or resin having high environmental resistance.

When a high voltage is applied to the protruding portion 12 of the metal wire constituting the electromagnetic wave observation unit 10 by the electromagnetic wave emitted from the electromagnetic wave generation source 100, the diode releases the voltage to the ground point located in the first space A.

As a result, a high voltage is not applied to the measurement unit 30, and the measurement unit 30 is protected.

In addition, in a case where the passive element circuit 14 is used, a high voltage is not applied to the passive element circuit 14, and the passive element circuit 14 is protected.

The electromagnetic wave detection device according to the eighteenth embodiment configured as described above also has effects similar to those of the electromagnetic wave detection devices according to the first embodiment to the seventeenth embodiment.

Furthermore, when a high voltage is applied to the protruding portion 12, since the voltage is released to the ground point located in the first space A, even in an environment where there is a high voltage or a rotating object such as a motor, a short circuit between the metal wire and the rotating object constituting the electromagnetic wave observation unit 10 and interposition of the metal wire in the rotating object can be prevented, and the electromagnetic wave observation unit 10 can be safely used without taking a complicated structure.

In addition, since the metal wire constituting the electromagnetic wave observation unit 10 has one end on the side of the extending portion 13 connected to the ground point located in the second space B and one end on the side of the protruding portion 12 connected to the ground point located in the first space A, the metal wire constituting the electromagnetic wave observation unit 10 can be easily laid with a simple structure, and the stability of the laying is maintained over a long period of time.

### Nineteenth Embodiment

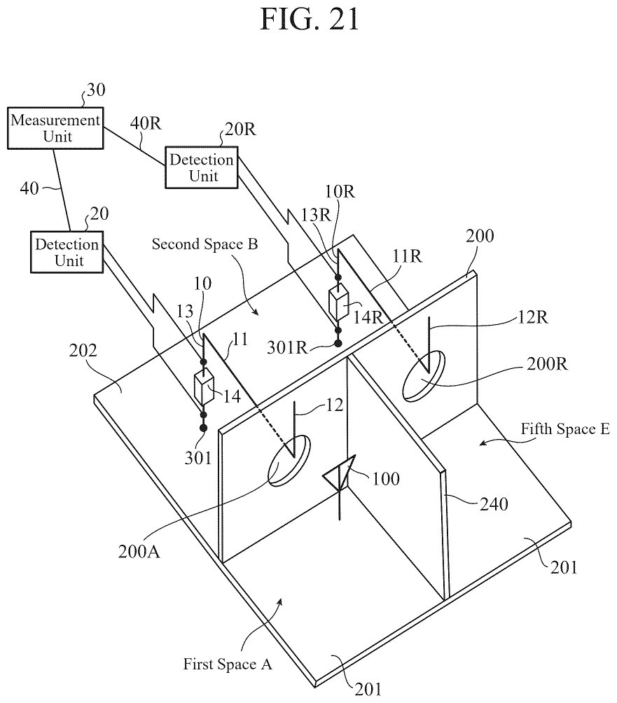

An electromagnetic wave detection device according to a nineteenth embodiment will be described with reference to FIG. 21.

The electromagnetic wave detection device according to the nineteenth embodiment is different from the electromagnetic wave detection device according to the first embodiment in that a disturbance noise detection unit is provided, the electromagnetic wave observation unit 10 includes a passive element circuit 14 connected between one end of the extending portion 13 of the metal wire and a ground point, and in terms of a ground point 301 at which one end portion of the electromagnetic wave observation unit 10, that is, the other terminal of the passive element circuit 14 is connected, and is the same in other points.

In FIG. 21, the same reference numerals as those in FIGS. 1 to 20 denote the same or corresponding parts.

The electromagnetic wave detection device according to the nineteenth embodiment includes an abnormal electromagnetic wave detecting unit that detects an electromagnetic wave emitted from the electromagnetic wave generation source 100, a disturbance noise detection unit that detects disturbance noise, and a measurement unit 30.

The abnormal electromagnetic wave detecting unit includes a first electromagnetic wave observation unit 10 and a first detection unit 20.

The first electromagnetic wave observation unit 10 includes: a first metal wire having a penetrating portion 11 that penetrates a through hole 200A formed in the partition plate 200 while being separated from a peripheral wall of the through hole, a protruding portion 12 that protrudes from the penetrating portion 11 to the first space A and receives an electromagnetic wave from the electromagnetic wave generation source 100, and an extending portion 13 that extends from the penetrating portion 11 to the second space B; and a first passive element circuit 14 in which one terminal is connected to one end of the extending portion 13 of the first metal wire and the other terminal is connected to a ground point 301.

The first detection unit 20 is a contact sensor of an active probe, such as a high-impedance probe or a field effect transistor probe, that accurately detects a voltage between both terminals of the first passive element circuit 14.

The first electromagnetic wave observation unit 10 and the first detection unit 20 in the abnormal electromagnetic wave detecting unit are the same as the electromagnetic wave observation unit 10 and the detection unit 20 in the electromagnetic wave detection device according to the eighth embodiment or the ninth embodiment.

The disturbance noise detection unit includes a second electromagnetic wave observation unit 10R and a second detection unit 20R.

The disturbance noise detection unit detects an electromagnetic wave that is disturbance noise present in a fifth space E.

The fifth space E is a space partitioned from the first space A by the third partition plate 240 and partitioned from the second space B by the partition plate 200.

The third partition plate 240 attenuates the propagation of the electromagnetic wave. The material of the third partition plate 240 is the material of the partition plate 200 or a similar material.

The partition plate 200 is formed with a second through hole 200R that communicates the fifth space E with the second space B.

The fifth space E is an environment having an electromagnetic environment similar to that of the first space A except that the electromagnetic wave generation source 100 does not exist. The first space A and the fifth space E are environments where similar disturbance noise enters, and are environments where the same level of disturbance noise exists.

The similarity mentioned here means that the electromagnetic waves in the environments of the first space A and the fifth space E are similar in amplitude and frequency except for the electromagnetic wave generation source 100.

In the case of the amplitude, the difference in amplitude of the disturbance noise between the first space A and the fifth space E is within +6 dB, and in the case of the frequency, the difference in frequency of the disturbance noise between the first space A and the fifth space E is within +3%.

For example, when the amplitude of the disturbance noise in the first space A is +10 m V, the amplitude of the disturbance noise in the fifth space E is +5 mV to +20 mV.

In addition, in a case where the frequency at which the frequency characteristic in the disturbance noise in the first space A is the maximum value is 100 MHZ, the frequency at which the frequency characteristic in the disturbance noise in the fifth space E is the maximum value is 97 MHz to 103 MHz.

In other words, when the operation of the electromagnetic wave generation source 100 is stopped and the electromagnetic waves in the first space A and the fifth space E are detected, the first space A and the fifth space E are in an electromagnetic environment in which a difference in amplitude is within +6 dB and a difference in frequency is within +3%.

The disturbance noise detection unit includes a second electromagnetic wave observation unit 10R and a second detection unit 20R.

The second electromagnetic wave observation unit 10R includes: a second metal wire having a penetrating portion 11R that penetrates a second through hole 200R formed in the third partition plate 240 while being separated from a peripheral wall of the second through hole, a protruding portion 12R that protrudes from the penetrating portion 11R to the fifth space E and receives an electromagnetic wave in the fifth space E, and an extending portion 13R that extends from the penetrating portion 11R to the second space B; and a second passive element circuit 14R in which one terminal is connected to one end of the extending portion 13 of the second metal wire and the other terminal is connected to a ground point 301R located on the second space side.

The second detection unit 20R uses a contact sensor of an active probe, such as a high-impedance probe or a field effect transistor probe, that accurately detects a voltage between both terminals of the second passive element circuit 14R.

The second electromagnetic wave observation unit 10R and the second detection unit 20R in the disturbance noise detection unit are preferably the same as the first electromagnetic wave observation unit 10 and the first detection unit 20 in the abnormal electromagnetic wave detecting unit.

In particular, the second metal wire 10R preferably has the same material and thickness as those of the first metal wire 10, has the same length, and has a symmetrical structure.

However, it is generally difficult to make the second metal wire 10R and the first metal wire 10 symmetrical with each other, and in a case where the lengths cannot be made equal depending on the place to be laid, the routing may be completely different.

In such a case, the separation distance between the second metal wire 10R and the surface of the partition plate 200 and the second through hole 200R and the parallel running distance between the second metal wire 10R and the surface of the partition plate 200 may be the same as the separation distance between the first metal wire 10 and the surface of the partition plate 200 and the through hole 200A and the parallel running distance between the first metal wire 10 and the surface of the partition plate 200, and the second metal wire 10R may be different from the first metal wire 10 in the entire length, the material, the thickness, and the symmetry.

In addition, the second passive element circuit 14R has the same characteristics as those of the first passive element circuit 14 when the second metal wire 10R and the first metal wire 10 are symmetric.

However, when the second metal wire 10R cannot be symmetric with the first metal wire 10, a circuit constant of the second passive element circuit 14R or a circuit topology of the second passive element circuit 14R is changed, and the second metal wire 10R and the first metal wire 10 are adjusted so as to approach a symmetric structure.

In addition, when adjustment in all frequency bands is difficult, the circuit constant of the second passive element circuit 14R is changed by narrowing down to a necessary frequency band, and adjustment is performed so as to have the same amplitude in the same frequency band without the electromagnetic wave generation source 100.

Detection and observation by the second electromagnetic wave observation unit 10R, and receiving the electromagnetic wave to be detected by the second detection unit 20R, and quantification of the signal from the second detection unit 20R are facilitated by the circuit design of the second passive element circuit 14R.

Note that if the receiver sensitivity is high and the electromagnetic wave detection signal is not buried in thermal noise without changing the circuit constant of the second passive element circuit 14R, the measurement unit 30 corrects the electromagnetic wave detection signal detected by the second detection unit 20R by performing signal processing.

The correction of the signal processing is adjusted so that the signal level from the second detection unit 20R at the set frequency coincides with the signal level from the first detection unit 20 when the electromagnetic wave generation source 100 operates normally or stops.

When the signal level from the second detection unit 20R does not coincide with the signal level from the first detection unit 20 even if the electromagnetic wave generation source 100 adjusts the signal level during the operation, or when the signal level is out of a preset range, it is regarded that an abnormality has occurred in the electromagnetic wave generation source 100.

Both the change of the circuit constant of the second passive element circuit 14R and the adjustment of the signal level from the second detection unit 20R may be performed.

The measurement unit 30 is a measuring instrument that monitors an abnormality in the electromagnetic wave generation source 100 by inputting an electromagnetic wave detection signal from the first detection unit 20 in the abnormal electromagnetic wave detecting unit via the coaxial cable 40, inputting an electromagnetic wave detection signal from the second detection unit 20R in the disturbance noise detection unit via the coaxial cable 40R, obtaining a difference signal between the electromagnetic wave detection signal from the first detection unit 20 and the electromagnetic wave detection signal from the second detection unit 20R, monitoring the difference signal as an electromagnetic wave detection signal for monitoring, and extracting an electromagnetic wave at the time of abnormality from the electromagnetic wave generation source 100.

That is, the measurement unit 30 monitors the difference between the voltage value detected by the first detection unit 20 in the abnormal electromagnetic wave detecting unit and the voltage value detected by the second detection unit 20R in the disturbance noise detection unit as the electromagnetic wave detection signal.

The measurement unit 30 is a measuring instrument that acquires time series waveforms such as an oscilloscope, a measuring instrument that measures frequency characteristics such as a spectrum analyzer, or a measuring instrument that measures a time waveform of a frequency of bandwidth in real-time such as a real-time spectrum analyzer.

As described above, the electromagnetic wave detection device according to the nineteenth embodiment includes, in the abnormal electromagnetic wave detecting unit, the first metal wire having the penetrating portion 11 that penetrates the through hole 200A formed in the partition plate 200 while being separated from the peripheral wall of the through hole, the protruding portion 12 that protrudes from the penetrating portion 11 to the first space A and receives the electromagnetic wave from the electromagnetic wave generation source 100, and the extending portion 13 that extends from the penetrating portion 11 to the second space, and the electromagnetic wave observation unit 10 having the first passive element circuit 14 in which one terminal is connected to one end of the extending portion 13 of the first metal wire and the other terminal is connected to the ground point 301. Therefore, the electromagnetic wave from the electromagnetic wave generation source 100 disposed of in the first space can be detected in the second space by using the electromagnetic wave observation unit 10 having a simple structure.

The electromagnetic wave detection device according to the nineteenth embodiment can prevent the first metal wire from being charged, and can hold the first metal wire in the laid state for a long period of time.

Furthermore, the electromagnetic wave detection device according to the nineteenth embodiment includes a disturbance noise detection unit having a configuration similar to that of the abnormal electromagnetic wave detecting unit, obtains a difference signal between the electromagnetic wave detection signal from the first detection unit 20 in the abnormal electromagnetic wave detecting unit and the electromagnetic wave detection signal from the second detection unit 20R in the disturbance noise detection unit, and monitors the difference signal as an electromagnetic wave detection signal for monitoring. Therefore, the electromagnetic wave detection device is less likely to be affected by the disturbance noise, has a large S/N ratio which is a ratio of the disturbance noise to the electromagnetic wave generated when the electromagnetic wave generation source 100 is abnormal, and can eliminate false detection and false detection.

In the electromagnetic wave detection device according to the nineteenth embodiment, as described in the fifth embodiment, one end of the extending portion 13 of the first metal wire may be connected to the ground point 301 without connecting the first passive element circuit 14, a current sensor may be used for the first detection unit 20, a current sensor may be attached to the extending portion 13 of the first metal wire, an electromagnetic wave detection signal may be output by the current sensor detecting a current flowing through the extending portion 13, one end of the extending portion 13R of the second metal wire may be connected to the ground point 301R without connecting the second passive element circuit 14R, a current sensor may be used for the second detection unit 20R, a current sensor may be attached to the extending portion 13R of the second metal wire, and an electromagnetic wave detection signal may be output by the current sensor detecting a current flowing through the extending portion 13R.

In the electromagnetic wave detection device according to the nineteenth embodiment, as described in the eighteenth embodiment, in the first space A, an impedance unit such as a diode may be connected between the open end of the protruding portion 12 of the first metal wire in the first electromagnetic wave observation unit 10 and the ground point located in the first space A, and an impedance unit such as a diode may be connected between the open end of the protruding portion 12R of the second metal wire in the second electromagnetic wave observation unit 10R and the ground point located in the fifth space E.

In this case, a 180-degree hybrid coupler (commonly known as balun) can be used as the first detection unit 20 and the second detection unit 20R, and a change can be confirmed in real-time.

In the electromagnetic wave detection device according to the nineteenth embodiment, the positional relationship between the first metal wire and the partition plate 200 in the first electromagnetic wave observation unit 10 is the positional relationship described in the first embodiment.

In the electromagnetic wave detection device according to the nineteenth embodiment, the electromagnetic wave generation source 100 is the component in which the electromagnetic wave is generated by the partial discharge, the cable in which the abnormality of the electric device is propagated to emit the electromagnetic wave, or the semiconductor device in which the surge voltage is generated, described in the first embodiment.

In the electromagnetic wave detection device according to the nineteenth embodiment, when the electromagnetic wave generation source 100 is a cable, as described in the tenth embodiment 10, the electromagnetic wave detection device includes the receiving unit 12A having the winding structure at the tip portion of the protruding portion 12 of the first metal wire in the first electromagnetic wave observation unit 10, as described in the eleventh embodiment, the electromagnetic wave detection device includes the receiving unit 12B that runs in parallel in a non-contact manner with the cable in the protruding portion 12 of the first metal wire, as described in the twelfth embodiment, the electromagnetic wave detection device includes the receiving unit 12C formed of a receiving conductor plate surrounding the periphery of the cable in the protruding portion 12 of the first metal wire, as described in the thirteenth embodiment, the electromagnetic wave detection device includes the receiving unit 12D made of a dielectric mold case with a built-in metal wire surrounding the periphery of the cable in the protruding portion 12 of the first metal wire, as described in the fourteenth embodiment, the protruding portion 12 of the first metal wire may have a receiving unit 12E formed of a dielectric mold case with a built-in metal wire surrounding the periphery of the cable.

In the electromagnetic wave detection device according to the nineteenth embodiment, when the electromagnetic wave generation source 100 is an insulator inside a distribution board or a bushing of a transformer of an oil type, a mold type, or the like, as described in the fifteenth embodiment, the receiving unit 12F made of a dielectric mold case with a built-in metal wire and surrounding the periphery of the insulator or the bushing may be provided at the tip portion of the protruding portion 12 of the first metal wire in the first electromagnetic wave observation unit 10.

In the electromagnetic wave detection device according to the nineteenth embodiment, as described in the sixteenth embodiment, the receiving conductor plate 12G thicker than the metal wire constituting the protruding portion 12 may be provided at the tip portion of the protruding portion 12 of the first metal wire in the first electromagnetic wave observation unit 10, and as described in the seventeenth embodiment, the receiving unit 12H having a winding structure having a surface parallel to the plane of the partition plate 200 may be provided at the tip portion of the protruding portion 12 of the first metal wire in the first electromagnetic wave observation unit 10.

Note that it is possible to freely combine the individual embodiments, to modify any components of the individual embodiments, or to omit any components in the individual embodiments.

### INDUSTRIAL APPLICABILITY

The electromagnetic wave detection device according to the present disclosure is suitable for monitoring the occurrence of an abnormality in an electromagnetic wave generation source such as a component in which an electromagnetic wave is generated by partial discharge, a cable in which an abnormality of an electric device is propagated and which emits an electromagnetic wave, and a semiconductor device generating a surge voltage.

### REFERENCE SIGNS LIST

10: electromagnetic wave observation unit (metal wire), 11: penetrating portion, 12: protruding portion, 12A to 12H: receiving unit, 13: extending portion, 14: passive element circuit, 20: detection unit, 30: measurement unit, 100: electromagnetic wave generation source, 200: partition plate (conductor plate), 200A, 210A, 220A, 230A: through hole, 210, 220: conductor plate, 230: second partition plate (conductor plate), 300, 301: ground point

1. An electromagnetic wave detection device comprising an electromagnetic wave observation unit and a detecting unit,
the detecting unit disposed of in a second space partitioned from a first space in which the electromagnetic wave generation source is disposed of by a partition plate to attenuate propagation of an electromagnetic wave and in which there is not the electromagnetic wave generation source,
the electromagnetic wave observation unit including a metal wire having a penetrating portion to penetrate a through hole formed in the partition plate through the first space and the second space while being separated from a peripheral wall of the through hole, a protruding portion to protrude from the penetrating portion to the first space apart from a surface of the partition plate without contact and receive the electromagnetic wave from the electromagnetic wave generation source, and an extending portion to extend from the penetrating portion to the second space apart from a rear surface of the partition plate without contact and
a coil connected between one end of the extending portion of the metal wire and the ground point, wherein
the detecting unit detects a voltage between both terminals of the coil.

2. The electromagnetic wave detection device according to claim 1, comprising:
Instead of just a coil,
a resonance circuit parallelly connecting a coil and a capacitor connected between one end of the extending portion of the metal wire and the ground point, wherein
the detecting unit detects a voltage between both terminals of the resonance circuit.

3. An electromagnetic wave detection device comprising an electromagnetic wave observation unit; a detecting unit; and a measurement unit,
the detecting unit disposed in a second space partitioned from a first space in which the electromagnetic wave generation source is disposed by a partition plate to attenuate propagation of an electromagnetic wave and in which there is not the electromagnetic wave generation source,
the measurement unit disposed in a forth space different from the first space and the second space, partitioned from the second space by a second partition plate to attenuate propagation of an electromagnetic wave,
the electromagnetic wave observation unit including a metal wire having a penetrating portion to penetrate a through hole formed in the partition plate through the first space and the second space while being separated from a peripheral wall of the through hole, a protruding portion to protrude from the penetrating portion to the first space apart from a surface of the partition plate without contact and receive the electromagnetic wave from the electromagnetic wave generation source, and an extending portion to extend from the penetrating portion to the second space apart from a rear surface of the partition plate without contact, one end placed in the second space side being connected to the ground point placed in the second space side, wherein
the detecting unit detects at least one of an electric field or a magnetic field superimposing on the extending portion of the metal wire without contact, and
the measurement unit receives electromagnetic wave detection signals from the detecting unit.

4. The electromagnetic wave detection device according to claim 3, wherein
the detecting unit includes a contact sensor detecting a voltage appearing between one end of the protruding portion of the metal wire and the ground point, and
the measurement unit receives electromagnetic wave detection signals from the detecting unit.

5. An electromagnetic wave detection device comprising: an abnormal electromagnetic wave detecting unit; a disturbance noise detection unit; and a measurement unit, wherein
the abnormal electromagnetic wave detecting unit includes: a first electromagnetic wave observation unit and a first detecting unit,
the first detecting unit disposed in a second space partitioned from a first space in which the electromagnetic wave generation source is disposed by a first partition plate to attenuate propagation of an electromagnetic wave and in which there is not the electromagnetic wave generation source,
the first electromagnetic wave observation unit including a first metal wire having a penetrating portion penetrating through a first space and a second space through a first through hole formed in a first partition plate, the penetrating portion being separated from a peripheral wall of the first through hole, a protruding portion protruding from the penetrating portion to the first space apart from a surface of the first partition plate without contact and receiving the electromagnetic wave from the electromagnetic wave generation source, and an extending portion extending from the penetrating portion to the second space apart from a rear surface of the first partition plate without contact, and a first circuit element connected between one end of the extending portion of the first metal wire and a ground point located on a side of the second space; and a first detection unit to detect a voltage between both ends of the first circuit element in the first electromagnetic wave observation unit,
the disturbance noise detection unit includes: a second electromagnetic wave observation unit and a second detecting unit,
the second detecting unit is disposed in the second space,
the second electromagnetic wave observation unit including a second metal wire having a penetrating portion penetrating through a fifth space and a second space formed on the first partition plate partitioning the fifth space and the second space in which an electromagnetic generation source does not exist partitioned by a second partition plate from the first space to attenuate propagation of an electromagnetic wave, the penetrating portion being separated from a peripheral wall of a second through hole, the protruding portion protruding from the penetrating portion to the fifth space apart from a surface of the first partition plate without contact and receiving the electromagnetic wave in the fifth space, and an extending portion extending from the penetrating portion to the second space apart from a rear surface of the first partition plate without contact, and a second circuit element connected between one end of the extending portion of the second metal wire and a ground point located on a side of the second space; and a second detection unit to detect a voltage between both ends of the second circuit element in the second electromagnetic wave observation unit, and
the measurement unit monitors a difference between a voltage value detected by the first detection unit in the abnormal electromagnetic wave detecting unit and a voltage value detected by the second detection unit in the disturbance noise detection unit as an electromagnetic wave detection signal.
